(19) United States
(12) Patent Application Publication
(10) Pub. No.: US 2006/0274586 A1
(43) Pub. Date: Dec. 7, 2006

(54) Semiconductor memory device with redundancy function

(76) Inventors: Tomohisa Takai, Kawasaki-shi (JP); Ryo Haga, Yokohama-shi (JP)

Correspondence Address: C. IRVIN MCCLELLAND;OBLON, SPIVAK, MCCLELLAND, MAIER & NEUSTADT, P.C., 1940 DUKE STREET, ALEXANDRIA, VA, 22314, US

(21) Appl. No.: 11/503,295

(22) Filed: Aug. 14, 2006

Related U.S. Application Data
(63) Continuation of application No. PCT/JP05/22513, filed on Dec. 1, 2005.

(30) Foreign Application Priority Data
Dec. 1, 2004 (JP) 2004-348906
Feb. 4, 2005 (JP) 2005-028811

(51) Int. Cl. G11C 29/00

(52) U.S. Cl. 365/200

(57) ABSTRACT

A fuse and fuse latch includes first and second fuse and fuse latches each serving as a redundancy information storage circuit. Fuse elements and a fuse latch are provided in each of the first and second fuse and fuse latches. The first and second fuse and fuse latches each output latched data as serial data to a fuse data transfer control circuit. The fuse data transfer control circuit serving as a redundancy information creation circuit is configured of a counter and a data transfer control circuit. The data transfer control circuit combines data output from the first and second fuse and fuse latches, thereby to create new data.

### CROSS REFERENCE TO RELATED APPLICATIONS

This is a Continuation Application of PCT Application No. PCT/JP2005/022513, filed Dec. 1, 2005, which was published under PCT Article 21(2) in English.

This application is based upon and claims the benefit of priority from prior Japanese Patent Applications No. 2004-348906, filed Dec. 1, 2004; and No. 2005-028811, filed Feb. 4, 2005, the entire contents of both of which are incorporated herein by reference.

### BACKGROUND OF THE INVENTION

1. Field of the Invention

The present invention relates to semiconductor memory devices with a redundancy function, and more specifically to a circuit which programs an address corresponding to a defective cell in a fuse element, thereby to generate a redundancy address from the programmed fuse element.

2. Description of the Related Art

In the field of semiconductor memory devices (referred to as “memories” hereinafter), such as dynamic random access memories (DRAMs), demands for increased storage capacity are growing. For large-scale memories (memories having a large capacity), it is essential to have a redundancy function to replace a defective cell which has occurred in a memory cell array with a redundancy cell to implement manufacturing yield improvement. An address corresponding to the defective cell is programmed into a redundancy fuse which is blown by laser light irradiation. The address, which is programmed into the fuse, is read at the start time of memory chip operation, and is stored into a fuse latch. The address stored in the fuse latch is compared with a memory-cell access address input from an external source. If the two addresses match, the redundancy cell instead of the defective cell is accessed, whereby compensation for the defective cell is performed.

Ordinarily, if a defective cell exists, substitution of redundancy cells is performed in units on the basis of either one row or one column in a memory cell array of memory cells containing the defective cell. In the case of row-basis substitution, that is, in the case of row redundancy, a row address is programmed into fuses. In the case of column-basis substitution, that is, in the case of column redundancy, a column address is programmed into fuses.

Jpn. Pat. Appln. KOKAI Publication No. 11-86588 describes an algorithm to share fuses among redundancy elements to save the number of address fuses used to substitute redundancy elements for a defective element.

In addition, Jpn. Pat. Appln. KOKAI Publication No. 2000-207896 discloses a technique capable of repairing also an error that occurs in burn-in testing of a semiconductor device packaged after laser repair in a wafer stage.

Further, U.S. Pat. No. 6,418,069 discloses a technique wherein a row line or column line containing a defective cell is replaced with one of redundant lines by programming. If an additional defective cell is detected after a predetermined number of redundant lines have been programmed, the programming of at least one of the redundant lines is canceled, and the redundant line is programmed for repairing another memory cell defect.

### BRIEF SUMMARY OF THE INVENTION

According to one aspect of the invention, there is provided a semiconductor memory device comprising: a plurality of redundancy information storage circuits each including a plurality of nonvolatile storage elements which store redundancy information used to replace a defective cell existing in a memory cell array by a spare cell in a spare memory cell array; and a redundancy information creation circuit which receives a plurality of redundancy information stored in the plurality of redundancy information storage circuits, combines the plurality of redundancy information, and thereby creates new redundancy information.

### BRIEF DESCRIPTION OF THE SEVERAL VIEWS OF THE DRAWING

FIG. 1 is a view showing exemplary redundancy fuses provided in a DRAM having row redundancy;

FIG. 2 is a view explaining conventional fuse blowing;

FIG. 3 is a view explaining exemplary conventional data compression;

FIG. 4 is a block diagram showing an overall configuration of a memory of a first embodiment;

FIG. 5 is a block diagram showing a practical configuration of a fuse box of FIG. 4;

FIG. 6 is a circuit diagram showing a practical configuration of first, second fuse and fuse latch of FIG. 5;

FIG. 7 is a circuit diagram showing a practical configuration of a fuse latch for row redundancy or a fuse latch for column redundancy of FIG. 4;

FIG. 8 is a circuit diagram showing a practical configuration of a fuse latch to which one fuse element of FIG. 6 is connected;

FIG. 9 is a timing chart showing exemplary operation of the fuse latch of FIG. 7;

FIG. 10 is a circuit diagram showing a practical configuration of a fuse latch circuit shown in FIG. 6;

FIG. 11 is a timing chart showing exemplary operation of the fuse latch of FIG. 10;

FIGS. 12A to 12D are views showing a manner in which data are assembled in a data transfer control circuit of the memory of the first embodiment;

FIG. 13 is a flowchart showing an algorithm used when new redundancy information is created in the data transfer control circuit of the memory of the first embodiment;

FIG. 14 is a block diagram showing a practical configuration of a fuse box in a memory of a second embodiment;

FIG. 15 is a view showing exemplary redundancy information to be written into first and second fuse and fuse latches in the memory of the second embodiment;

FIG. 16 is a flowchart showing an algorithm used when new redundancy information is created in a data transfer control circuit of FIG. 14;

FIG. 17 is a view showing exemplary redundancy information to be written into first and second fuse and fuse latches in a memory of a modified embodiment of the second embodiment;

FIG. 18 is a flowchart showing an algorithm used when new redundancy information is created in a data transfer control circuit of the memory of the modified embodiment of the second embodiment;

FIG. 19 is a view showing exemplary redundancy information to be written into first and second fuse and fuse latches in a memory of a third embodiment;

FIG. 20 is a flowchart showing an algorithm used when new redundancy information is created in a data transfer control circuit of the memory of the third embodiment;

FIG. 21 is a block diagram showing a practical configuration of a fuse box in a memory of a fourth embodiment;

FIG. 22 is a view showing exemplary redundancy information before being written into first fuse and fuse latches and exemplary redundancy information after having been written thereto in the memory of the fourth embodiment;

FIG. 23 is a flowchart showing an algorithm used when compressed redundancy information are expanded in data transfer control circuit of FIG. 21 and transferred to a memory macro;

FIG. 24 is a block diagram showing a practical configuration of a fuse box in a memory of a fifth embodiment;

FIG. 25 is a view showing exemplary redundancy information before being written into a first fuse and fuse latch and exemplary redundancy information after having been written thereto in the memory of the fifth embodiment;

FIG. 26 is a flowchart showing an algorithm used when compressed redundancy information are expanded in a data transfer control circuit of FIG. 24 and transferred to a memory macro;

FIG. 27 is a block diagram showing a practical configuration of a fuse box in a memory of a sixth embodiment;

FIG. 28 is a view showing exemplary redundancy information to be written into a first and second fuse and fuse latch in the memory of the sixth embodiment;

FIG. 29 is a flowchart showing an algorithm used when new redundancy information is created in a data transfer control circuit of the memory of the sixth embodiment;

FIG. 30 is a block diagram showing a practical configuration of a fuse box in a memory of a modified embodiment of the sixth embodiment;

FIG. 31 is a flowchart showing an algorithm used when new redundancy information is created in a data transfer control circuit of the memory of the modified embodiment of the sixth embodiment;

FIG. 32 is a view showing exemplary redundancy information to be written into a first and second fuse and fuse latch in a memory of a seventh embodiment;

FIG. 33 is a flowchart showing an algorithm used when new redundancy information is created in a data transfer control circuit of the memory of the seventh embodiment;

FIG. 34 is a view showing redundancy word lines, address values to be programmed into first and second Fusesets, and address values to be actually transferred to a memory macro in the memory of the six embodiment or the modified embodiment thereof;

FIG. 35 is a view explaining principles of a memory of an eighth embodiment;

FIG. 36 is a block diagram showing a practical configuration of a fuse box in the memory of the eighth embodiment;

FIG. 37 is a view showing exemplary redundancy information to be written into a first and second fuse and fuse latch provided in the fuse box of FIG. 36 and exemplary data to be transferred to a memory macro;

FIG. 38 is a flowchart showing an algorithm used when new redundancy information is created in a data transfer control circuit of the memory of the eighth embodiment; and

FIG. 39 is a view showing redundancy word lines, address values to be programmed into first and second Fusesets, and address values to be actually transferred to the memory macro in the memory of the eighth embodiment.

### DETAILED DESCRIPTION OF THE INVENTION

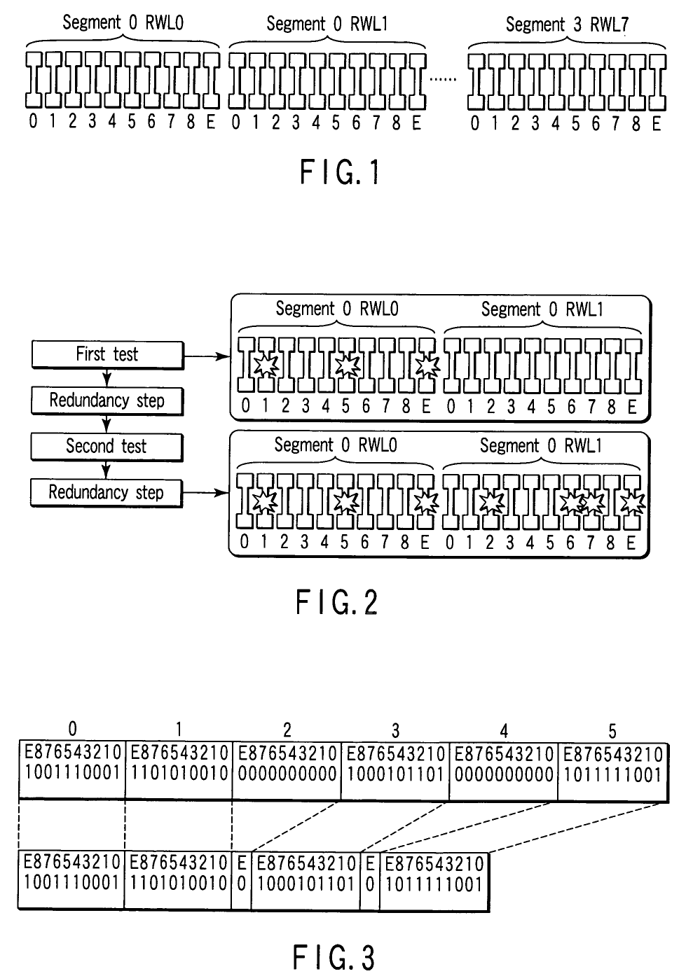

FIG. 1 shows exemplary redundancy fuses provided in a DRAM having row redundancy. In this case, a memory cell array is configured of four segments, namely, Segments 0 to 3. Eight redundancy word lines for compensation for defective cells are disposed in the respective Segment. Eight Fusesets corresponding to the eight redundancy word lines (RWL0 to RWL7) are provided in the respective Segment. Each Fuseset is configured of one Enable fuse and nine address fuses. The Enable fuse is used to program whether or not the Fuseset will be used, and the nine address fuses are used to designate an address that uses the redundancy. In this case, the number of normal word lines per Segment is assumed to be 512.

Memory testing includes a variety of processing steps, and the address causing defect is different depending on the processing step. As such, cases occur where it is desired that testing is performed on a chip in, for example, a wafer state, fuse blowing is performed in accordance with the result of the testing, the chip is then packaged, testing is again performed thereon, and fuse blowing is further performed thereon. This case is exemplified in FIG. 2.

FIG. 2 shows an example wherein fuse blowing is performed to use the redundancy word line RWL0 in the Segment 0 after the first testing, and the redundancy word line RWL1 in the Segment 0 in an unused portion is subjected to fuse blowing. Thus, in the case where that the fuses are uniquely correlated to the redundancy word lines, even when a plurality of testing steps are performed, unused fuses can be used.

However, since such fuse elements use a large occupation area on the chip, there is a demand for reducing the number of the fuse elements. A scheme used to reduce the number of fuses is a fuse data compression scheme. An example of the data compression scheme is shown in FIG. 3. With reference to FIG. 3, shown on the upper side is data before being compressed, and shown on the lower side is data after having being compressed. In this example, data (ten data 0s) of Fusesets 2, 4 including an unblown Enable fuse (E) are represented by a 0. Thereby, the number of fuses is reduced from 60 required before compression to 42. Generally, a redundancy usage rate per post-production memory chip is about less than half, so that the number of fuses can be reduced by about 70% in accordance with the above-described scheme.

However, with such the data compression scheme being used, problems occur when performing fuse blowing in a plurality of redundancy steps. For example, suppose that fuse blowing as shown in FIG. 3 is performed in the first redundancy step. In this case, even when the necessity arises for using the Fuseset 2, 4 in the second redundancy step, since fuse blowing is an irreversible process, the second fuse blowing cannot be performed. As such, it is difficult for the fuse data compression and multiple fuse blowing processes to be compatible with each other.

### First Embodiment

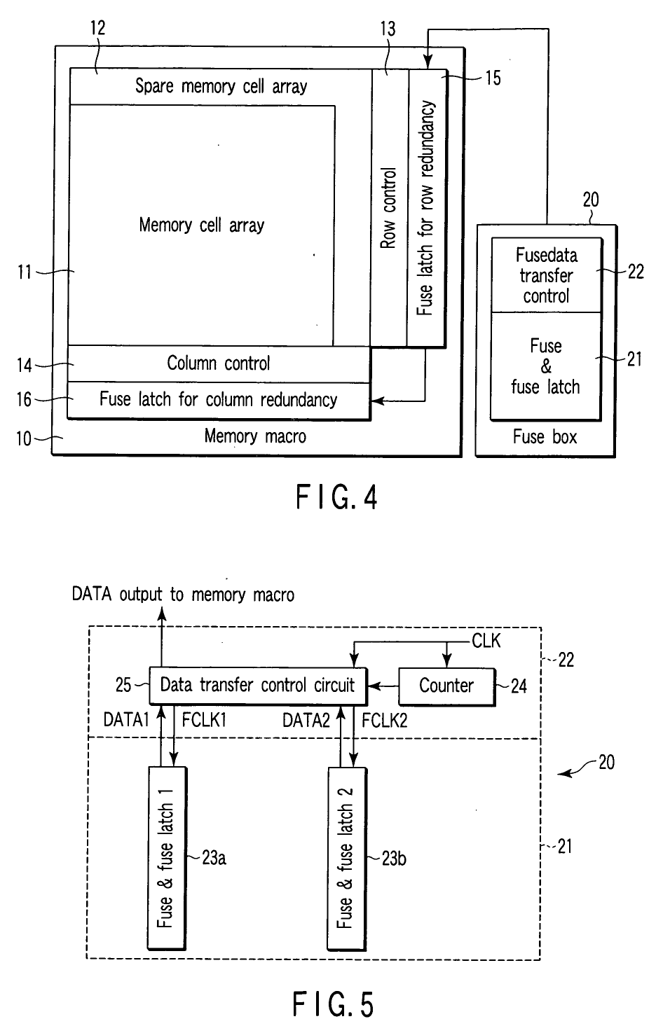

FIG. 4 is a block diagram showing an overall configuration of a memory of a first embodiment. The memory is, broadly, configured of a memory macro 10 and a fuse box 20.

The memory macro 10 includes a memory cell array 11, a spare memory cell array 12, a row control circuit 13, a column control circuit 14, a fuse latch 15 for row redundancy, and a fuse latch 16 for column redundancy.

A plurality of memory cells is disposed in a matrix in the memory cell array 11. A plurality of memory cells disposed in a same row is commonly connected to a corresponding one of a plurality of word lines. A plurality of memory cells disposed in a same column is commonly connected to a corresponding one of a plurality of bitlines.

A plurality of redundancy word lines and a plurality of redundancy bitlines are provided in the spare memory cell array 12. When a defective cell exists in the memory cell array 11, a plurality of spare cells used for substitution to compensate for the defective cell are connected to the individual redundancy word line and bitline.

The row control circuit 13 performs selection of either a word line in the memory cell array 11 or a redundancy word line in the spare memory cell array 12 when accessing memory cells of the memory cell array 11. The selection is performed in accordance with redundancy information containing a supplied row address (selection information) and a redundancy row address stored in the row-redundancy fuse latch 15.

The column control circuit 14 performs selection of either a bitline in the memory cell array 11 or a redundancy bitline in the spare memory cell array 12 when accessing memory cells of the memory cell array 11. The selection is performed in accordance with redundancy information containing a supplied column address (selection information) and a redundancy column address stored in the column-redundancy fuse latch 16.

When a defective cell exists in the memory cells of the memory cell array 11, the row-redundancy fuse latch 15 stores redundancy information containing a redundancy row address used to substitute one row of spare cells of the spare memory cell array 12 for one row of memory cells of the memory cell array 11 that contain the defective cell.

When a defective cell exists in the memory cells of the memory cell array 11, the column-redundancy fuse latch 16 stores redundancy information containing a redundancy column address used to substitute one column of spare cells of the spare memory cell array 12 for one column of memory cells of the memory cell array 11 that contain the defective cell.

Access is made to a memory cell or spare cell positioned at the intersection of the word line or redundancy word line selected by the row control 13 and the bitline or redundancy bit line selected by the column control 14. In the event of data writing, data to be written are supplied to the selected memory cell through a data input/output (I/O) and a sense amplifier, whereby the data writing is performed thereinto. In the event of data reading, data stored in the selected memory cell is read by the sense amplifier and is output to the outside of the memory through the data I/O.

The fuse box 20 creates redundancy information for being stored into the row-redundancy fuse latch 15 and the column-redundancy fuse latch 16. The fuse box 20 is configured of a fuse and fuse latch 21 and a fuse data transfer control 22. The fuse and fuse latch 21 includes a plurality of fuse elements programmed with redundancy information containing, for example, a redundancy address. The fuse data transfer control circuit 22 is supplied with the redundancy information programmed in the fuse and fuse latch 21. Then the fuse data transfer control circuit 22 combines the redundancy information to thereby create new redundancy information, and transfers the created redundancy information to the row-redundancy fuse latch 15 and column-redundancy fuse latch 16 in the memory macro 10.

FIG. 5 is a block diagram showing a practical configuration of the fuse box 20 of FIG. 4. A plurality of fuse and fuse latches, which work as redundancy information storage circuits, are provided in the fuse and fuse latch 21. The present embodiment shows an exemplary case where as the above-described plurality of fuse and fuse latches, two fuse and fuse latches, namely first and second fuse and fuse latches 23a and 23b, are provided.

In the respective first, second fuse and fuse latches 23a, 23b, a plurality of fuse elements are provided as nonvolatile storage elements, and a plurality of fuse latches are provided corresponding to the individual fuse elements, whereby data programmed in the individual fuse elements are latched. In synchronization with a transfer clock signals FCLK1 and FCLK2 being supplied, the first and second fuse and fuse latches 23a and 23b respectively supply data as serial data DATA1 and DATA2, which have been latched in the plurality of fuse latches, to the fuse data transfer control circuit 22.

The fuse data transfer control circuit 22 serving as a redundancy information creation circuit is configured of, for example, a counter 24 and a data transfer control circuit 25. The counter 24 counts clock signals CLK being supplied. A count output of the counter 24 is supplied to the data transfer control circuit 25. The data transfer control circuit 25 supplies the transfer clock signals FCLK1 and FCLK2 to the respective first and second fuse and fuse latches 23a and 23b. In addition, the data transfer control circuit 25 receives the serial data DATA1 and DATA2 from the first and second fuse and fuse latches 23a and 23b, combines the two items of data to create new data, and transfers the new data to the memory macro 10.

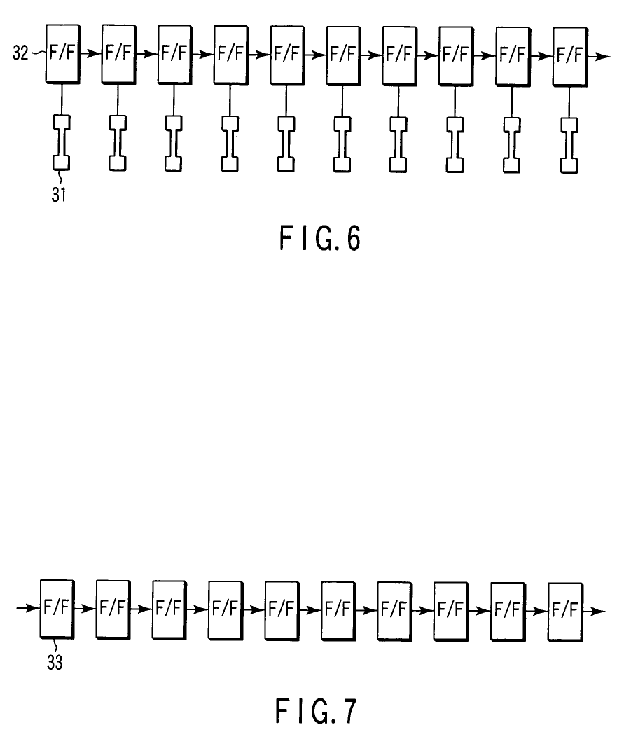

FIG. 6 is a detailed circuit diagram showing a practical configuration of the first, second fuse and fuse latches (redundancy information storage circuits) 23a, 23b of FIG. 5. A plurality of fuse elements 31 are each a programmable nonvolatile storage element, and redundancy information containing, for example, a redundancy address is programmed into the plurality of fuse elements. A plurality of fuse latches 32 each including a flipflop (F/F) are connected to the individual fuse elements 31. The plurality of fuse latches 32 are connected in series.

In the present embodiment, it is assumed that the plurality of fuse elements 31 provided in the first fuse and fuse latch 23a are programmed immediately after testing performed in the wafer state. For this reason, elements having a structure blowable by irradiation of laser light are employed for the fuse elements. However, it is assumed that the plurality of fuse elements 31 provided in the second fuse and fuse latch 23b are programmed after testing performed after the chip has been packaged. For this reason, elements having a structure blowable by electrical means, such as by applying electric current, are employed for the fuse elements.

Redundancy information programmed into the individual fuse elements 31 are latched by corresponding fuse latches 32. Redundancy information latched by the plurality of fuse latches 32 are serially transferred in synchronization with the transfer clock signal FCLK1 or FCLK2 and supplied as the serial data DATA1 or DATA2 to the data transfer control circuit 25.

FIG. 7 is a circuit diagram showing a practical configuration of the row-redundancy and column-redundancy fuse latches 15, 16 of FIG. 4. In the respective fuse latches 15, 16, a plurality of series connected fuse latches 33 each including a flip-flop (F/F) are provided. New data created in the fuse data transfer control circuit 22 is serially supplied to an end portion of the plurality of fuse latches 33, and is then serially transferred through the plurality of fuse latches 33. Thereby, redundancy information containing, for example, a redundancy address is set to the fuse latches 15, 16.

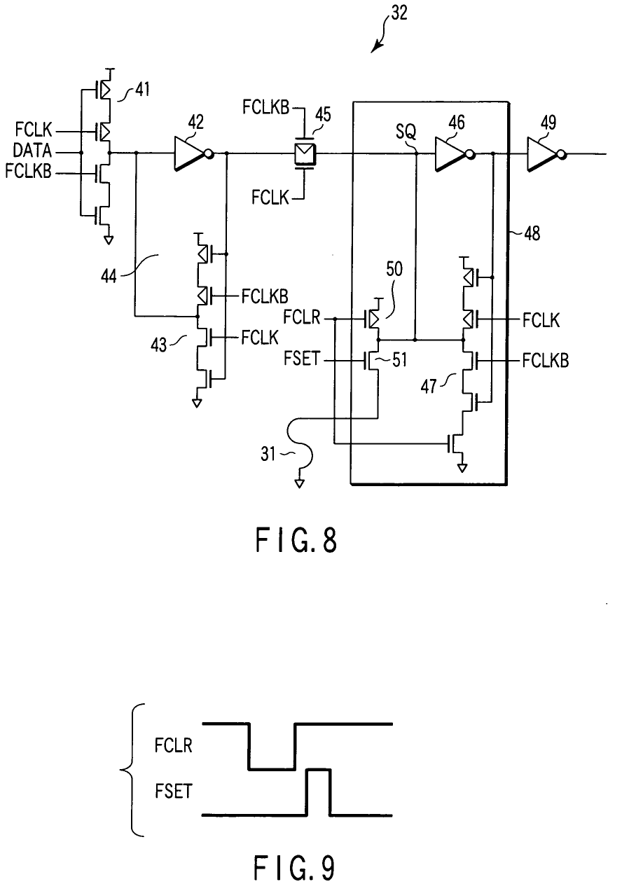

FIG. 8 is a circuit diagram showing a practical configuration of the fuse latch 32 to which one of the fuse elements 31 of FIG. 7 is connected. The fuse latches 32 is configured to include a clocked inverter circuit 41 that is supplied with data DATA transferred from a preceding fuse latch 32; a latch 44 that is configured of an inverter circuit 42 and a clocked inverter circuit 43 and that latches an output of the clocked inverter circuit 41; a CMOS transfer gate 45 that transfers and controls an output of the latch 44; a latch 48 that includes an inverter circuit 46 and a clocked inverter circuit 47, wherein data programmed into the fuse elements 31 is set and data are supplied from the preceding CMOS transfer gate 45; and an inverter circuit 49 that is supplied with an output of the latch 48.

In the latch 48 there are further provided a PMOS transistor 50 to clear an input node SQ of the latch 48, and an NMOS transistor 51 to set data programmed into the fuse elements 31 is set to an input node SQ.

The clocked inverter circuits 41 and 47 are each controlled by a clock signal FCLK (any one of FCLK1 and FCLK2) and an inverse clock signal FCLKB, and the CMOS transfer gate 45 is controlled by the inverse clock signal FCLKB and the clock signal FCLK.

As shown in a timing chart of FIG. 9, in the event of transfer of the data programmed into the fuse elements 31 to the fuse latch 32, a clear signal FCLR and a set signal FSET are input. When the clear signal FCLR becomes the “L” level, the transistor 50 turns on and the input node SQ of the latch 48 is forcedly cleared to the “H” level. Thereafter, when the set signal FSET becomes the “H” level, the transistor 51 turns on. In this state, if the fuse elements 31 is blown, then the input node SQ remains at “H”. On the other hand, if the fuse elements 31 is not blown, then the input node SQ goes “L” level. Thereafter, the clock signal FCLK and the inverse clock signal FCLKB are supplied as transfer signals, data is serially transferred toward the backstage via the plurality of fuse latches 32.

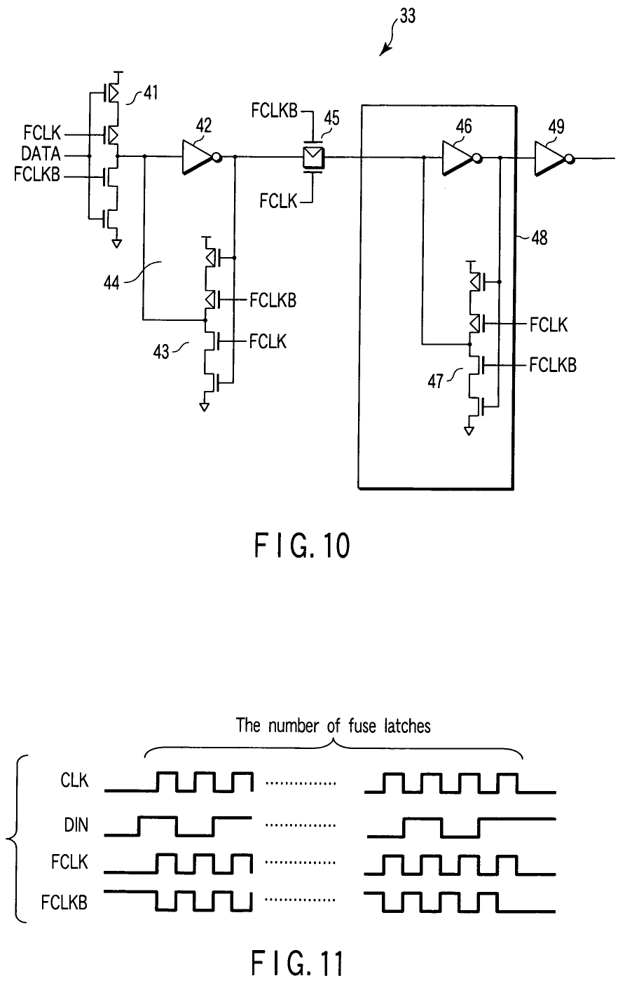

FIG. 10 is a circuit diagram showing a practical configuration of one of the fuse latches 33 of FIG. 7. In comparison to the fuse latch 32 shown in FIG. 8, the fuse latch 33 is only different in that the two transistors 50 and 51 in the latch 48 are omitted, but the same as the fuse latch 32 for other configuration portions, so that description of the configuration thereof will not be repeated.

In the fuse latch 33 shown in FIG. 10, the clock signal FCLK and the inverse clock signal FCLKB are supplied as transfer clock signals, thereby data are transferred in the plurality of fuse latches 33 connected in series.

FIG. 11 is a timing chart formed during data transfer in the fuse latches 15, 16 where the plurality of fuse latches 33 of the type shown in FIG. 10 are provided. In FIG. 11, DIN denotes data for being transferred. The clock signal FCLK and the inverse clock signal FCLKB are activated multiple times corresponding to the number of fuse latches 33 provided in the fuse latches 15, 16. The clock signal FCLK and the inverse clock signal FCLKB are generated in the manner that clock signals CLK are counted by a counter (not shown). Thereby, redundancy information combined in the data transfer control circuit 25 and transferred are transferred to and set at predetermined locations of the plurality of fuse latches 33 provided in the fuse latches 15, 16.

Operation of the memory having the above-described configuration will now be described here. For facilitating understanding, description will be made with reference to an exemplary case where, when a defective cell has occurred in the memory cell array 11, the defective cell is replaced by a spare cell in the spare memory cell array 12 through substitution performed in units of one row.

First, the first testing is performed. The testing is performed in the wafer state, for example. In this event, if a defective cell is found in the memory cell array 11, then redundancy information including an address of a word line containing the defective cell is programmed into the first-operation dedicated first fuse and fuse latch 23a of FIG. 5. The programming is performed in the manner that the fuse element is cut (blown) by using laser light irradiated from a laser radiation device. In this event, the second-operation dedicated fuse and fuse latch 23b of FIG. 5 is not programmed.

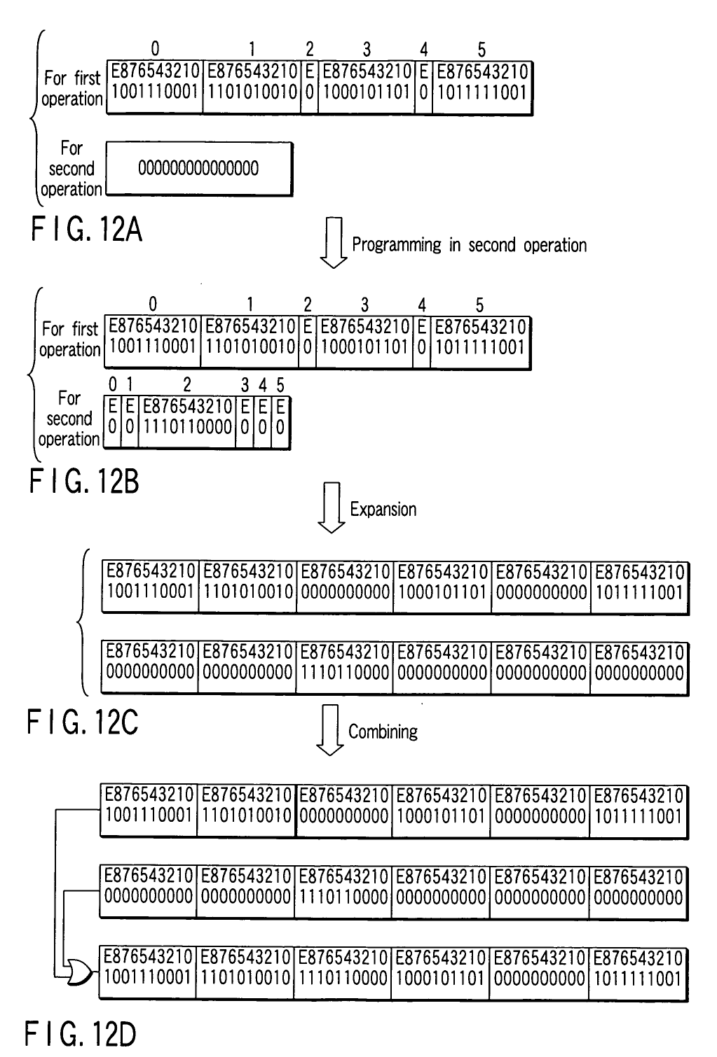

The redundancy information to be programmed into the first fuse and fuse latch 23a is compressed by a compression scheme as the type described by reference to FIG. 3. For example, as shown in FIG. 12A, when using redundancy word lines 0, 1, 3, and 5 (=0th, 1st, 3rd, and 5th word lines) in six redundancy word lines, data 1 (=binary or logical 1) is programmed into Enable (E) fuse in ten fuses of each of Fusesets 0, 1, 3, and 5 (=0th, 1st, 3rd, and 5th Fusesets), and an address for designating an address using the row redundancy is programmed into the remaining nine address fuses of the respective Fuseset. For unused Fusesets 2 and 4 (=2nd and 4th Fusesets), similarly as in the case described by reference to FIG. 3, data composed of ten 0s are compressed into data composed of a single 0, and 0 is programmed into the respective one Enable fuse.

Subsequently, the second testing is performed. The testing is performed after the chip is packaged, for example. In this event, if a defective cell is found in the memory cell array 11, then redundancy information including an address of a word line containing the defective cell is programmed into the second-operation dedicated second fuse and fuse latch 23b of FIG. 5. The programming is performed in the manner that the fuse element is cut (blown) by applying a large current flow from a control circuit (not shown). In this event, the first-operation dedicated first fuse and fuse latch 23a of FIG. 5 is not programmed.

Also the redundancy information to be programmed into the second fuse and fuse latch 23b is compressed by a compression scheme as the type described by reference to FIG. 3. The redundancy word lines 0, 1, 3, and 5 in the six redundancy word lines are already used, and substitution is already performed with the spare cells of the spare memory cell array 12. As such, as shown in FIG. 12B, ten-0s data are compressed into a single-0 data, and 0 is programmed into one Enable fuse, respectively.

In the event that another defective cell is found, as shown in FIG. 12B, when using the word line 2, data 1 is programmed into Enable (E) fuse in ten fuses of one Fuseset, and an address for designating an address using the row redundancy is programmed into the remaining nine address fuses. For Fuseset 4 unused even in the second testing, ten-0s data are compressed into a single-0 data, and 0 is programmed into the one Enable fuse.

After power voltage is supplied to the memory chip and before memory access is started, redundancy information as shown in FIG. 12B and written in the first and second fuse and fuse latches 23a and 23b of FIG. 5 are serially read and supplied to the data transfer control circuit 25. Then in the data transfer control circuit 25, the two items of redundancy information supplied from the first and second fuse and fuse latches 23a and 23b are combined, thereby creating new redundancy information. The created new redundancy information is serially transferred to the row-redundancy fuse latch 15 and column-redundancy fuse latch 16 in the memory macro 10, thereby being set in the fuse latches 15 and 16.

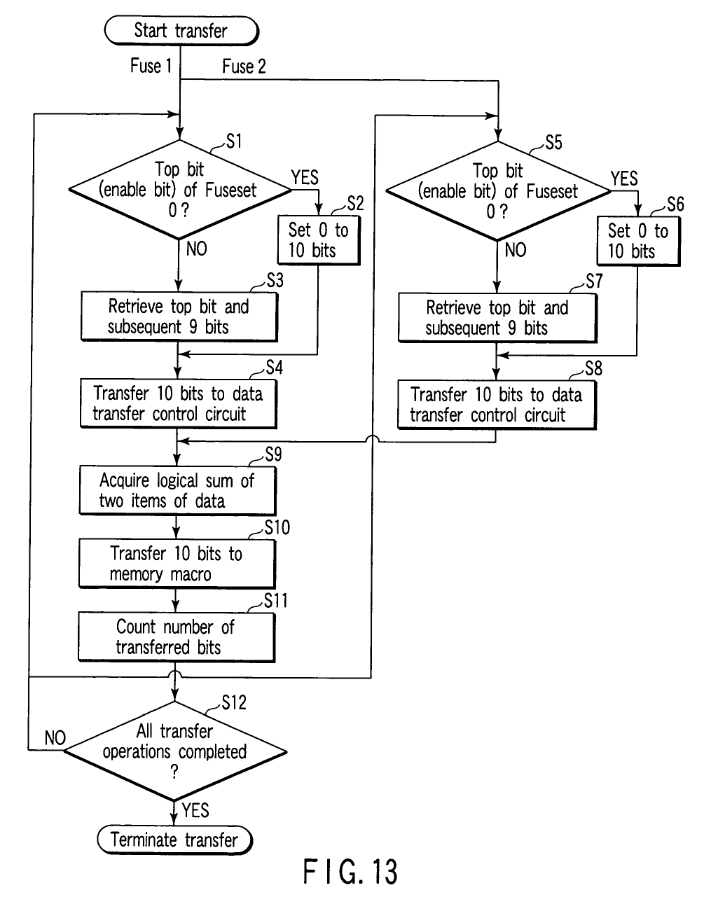

FIG. 13 is a flowchart showing an algorithm used when new redundancy information is created in the data transfer control circuit 25. According to the algorithm, synchronously with the start of data transfer, compressed data programmed in the plurality of fuse elements for each of the first and second operations are expanded and concurrently subjected to transfer processing, logical sums of individual two items of data are acquired during the transfer and combined into new data, and the data are supplied to the memory macro 10.

First, after start of transfer, the algorithm determines whether or not the top, i.e., Enable bit, of data (Fuse 1) transferred from the first fuse and fuse latch 23a is 0 (Step S1). If the Enable bit is 0, then data composed of ten 0 bits are generated (Step S2). If the Enable bit is 1, a first bit and nine bits subsequent thereto are retrieved (Step S3). Then the ten bits of data are transferred to the data transfer control circuit 25 (Step S4). Compressed data written in this manner into the first fuse and fuse latch 23a is then expanded.

On the other hand, the algorithm determines whether or not the top, i.e., the Enable bit, of data (Fuse 2) transferred from the second fuse and fuse latch 23b is 0 (Step S5). If the Enable bit is 0, then ten-0-bits data is generated (Step S6). If the Enable bit is 1, then data of the first bit and subsequent nine bits are retrieved (Step S7). Thereafter, the ten-0-bits data are transferred to the data transfer control circuit 25 (Step S8). In this manner, compressed data written in the second fuse and fuse latch 23b are expanded.

Subsequently, at Step S9, the logical sum of the ten-bits data expanded and transferred at Step S4 and the ten-bits data expanded and transferred at Step S8 is acquired in units of bit, whereby the data are combined into new redundancy information (Step S9) and transferred to the memory macro 10 (Step S10). Then, the number of the transferred bits is counted (Step S11), and it is determined whether or not all transfer operations are completed (Step S12). If all the transfer operations are not yet completed, then the algorithm returns to Steps S1 and S5. If all the transfer operations are completed, then the transfer to the memory macro 10 terminates.

FIG. 12C shows two items of exemplary redundancy information after completion of expansion of all data. FIG. 12D shows the manner wherein the new redundancy information is generated through combination performed by acquiring the logical sums of data of the two items of redundancy information depicted in FIG. 12C.

In the above, the memory of the present embodiment has been described with reference to the case where the defective cell existing in the memory cell array 11 is replaced by a spare cell existing in the spare memory cell array 12 through the substitution performed in units of the row. Alternately, however, such a defective cell can be replaced by a spare cell existing in the spare memory cell array 12 through substitution performed in units of a column. Still alternately, the two substitution methods can be used in combination.

Further, the memory of the embodiment has been described with reference to the case where the first and second fuse and fuse latches 23a and 23b are provided as examples of the plurality of fuse and fuse latches, thereby to perform two programming operations with redundancy information in accordance with the results of two operations of testing. However, three or more fuse and fuse latches may be provided thereby to perform three or more programming operations with redundancy information in accordance with results of three or more testing operations.

Thus, in the memory of the above-described present embodiment, although the fuse data are compressed, fuse-data programming can be performed multiple times

### Second Embodiment

According to the first embodiment described above, when the Enable bit is 0, all the data to be programmed into one fuse set are each recognized to indicate 0, and ten-bits data are compressed into data composed of a single 0 bit. In this connection, a case is now contemplated in which eight Segments are provided in the memory cell array 11 of FIG. 4, and eight redundancy word lines exist in units of one Segment.

It is assumed that, in the memory of the first embodiment, the memory cell array 11 is configured of 32 Segments, namely, Segments 0 to 31, and eight Fusesets are provided corresponding to eight redundancy word lines disposed in the respective Segment. In this case, a necessary number of fuse elements within the second fuse and fuse latch 23b which are used in the second programming operation is at least 256 (=32×8). The number of fuse elements for enabling at least three defective cells by the second programming operation is, therefore, 283 (=(32×8)+(9×3)). In the 283 fuse elements, 253 fuse elements are each programmed with the post-compression data 0, so that the fuse-element use efficiency is low.

In view of the above, the second embodiment is made to increase the fuse-element use efficiency by reducing the number of fuse elements of the second fuse and fuse latch 23b that is used in the second programming operation. Accordingly, the present embodiment employs fuse data compression schemes different from each other for the first operation and the second operation.

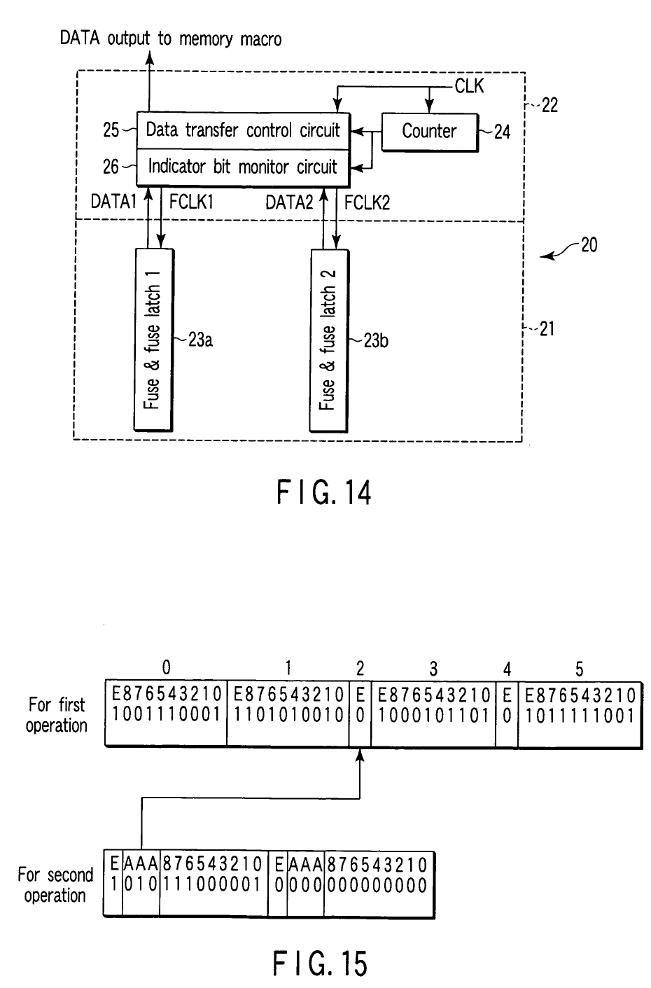

FIG. 14 is a block diagram showing a practical configuration of a fuse box 20 in a memory of the second embodiment. Similarly as in the case shown in FIG. 5, as examples of the plurality of fuse and fuse latches, first and second fuse and fuse latches 23a and 23b are provided in the fuse and fuse latch 21.

In the fuse data transfer control circuit 22, an indicator bit monitor circuit 26 is provided in addition to the counter 24 and the data transfer control circuit 25.

FIG. 15 is a view showing exemplary redundancy information to be written into first, second fuse and fuse latches in the memory of the second embodiment. Data to be written into the first fuse and fuse latch 23a are compressed by using a compression scheme similar to that used in the first embodiment. That is, the Fuseset to be programmed with one row-redundancy address is configured of ten fuse elements, and ten-0-bits data are compressed into single-0-bit data.

In the second-operation dedicated second fuse and fuse latch 23b, one Fuseset is configured of 13 fuse elements. In the 13 fuse elements, three-bit composed indicator bits are programmed into three fuse elements (A) subsequent to the top-positioned Enable fuse (E). The indicator bits are used to provide data indicating that data to be programmed into the Fuseset is substituted for which one of first-operation dedicated Fusesets. In the example shown in FIG. 15, three-bit composed indicator bits in data programmed into 13 fuse elements of the first Fuseset for the second operation are “010”. In this case, the indicator bits indicate that the data is substituted for the second data in the first-operation dedicated Fuseset.

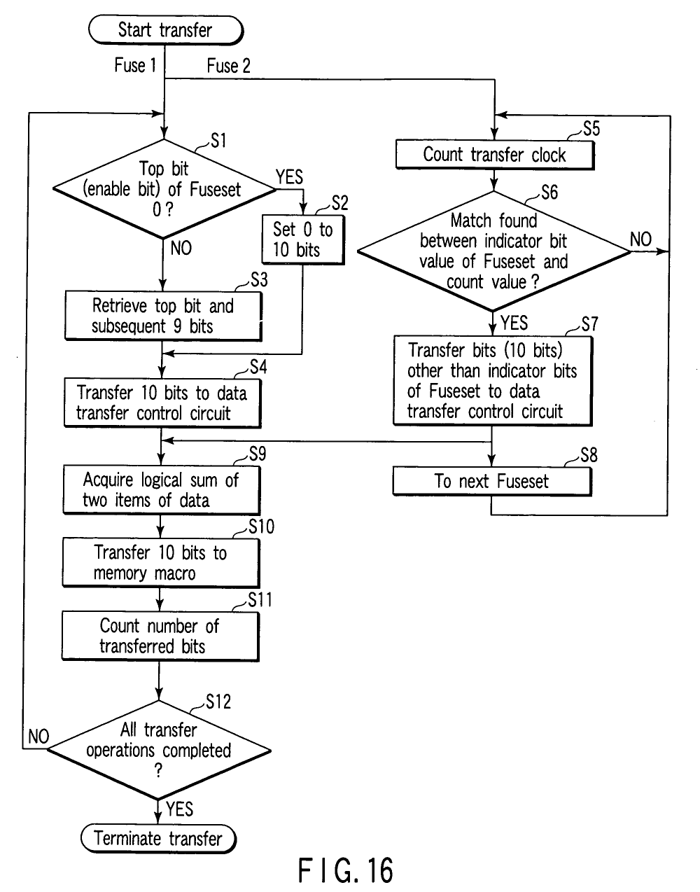

FIG. 16 is a flowchart showing an algorithm used when new redundancy information is created in the data transfer control circuit 25 of FIG. 14. According to the algorithm, after the start of data transfer, data programmed into the compressed state in the plurality of fuse elements for each of the first and second operations are expanded and concurrently subjected to transfer processing, logical sums of two items of data are acquired during the transfer and combined into new data, and the data are supplied to the memory macro 10.

First, after start of transfer, the algorithm determines whether or not the top, i.e., Enable bit, of data (Fuse 1) transferred from the first fuse and fuse latch 23a is 0 (Step S1). If the Enable bit is 0, then ten-0-bits data is generated (Step S2). If the Enable bit is 1, then a first bit and nine bits subsequent thereto are retrieved (Step S3). In this manner, compressed data written in the first fuse and fuse latch 23a are expanded, and the expanded ten-bits data are transferred to the data transfer control circuit 25 (Step S4).

On the other hand, after the start of transfer, a transfer clock is counted (Step S5). Then, it is determined whether or not a match is found between a transfer-clock count result and a value of indicator bits of data (Fuse 2) transferred from the second fuse and fuse latch 23b (Step S6). As a consequence, if a match is not found, then the algorithm returns to Step S5, whereat the transfer clock is again counted. If a match is found at Step S6, then ten-bits data, i.e., data other than the indicator bits, are transferred to the data transfer control circuit 25 (Step S7). For a comparison between a subsequent count value and indicator bits, indicator bits of a subsequent data (Fuse 2) are referenced (Step S8). That is, indicator bits of the second-operation dedicated second fuse and fuse latch 23b are referenced sequentially from the top.

Subsequently, the logical sum of the ten-bits data transferred at Step S4 and the ten-bits data transferred at Step S7 is acquired in units of the bit, whereby the data are combined into new redundancy information (Step S9) and transferred to the memory macro 10 (Step S10). Then, the number of the transferred bits is counted (Step S11), and it is determined whether or not all transfer operations are completed (Step S12). If all the transfer operations are not yet completed, then the algorithm returns to Steps S1 and S5. If all the transfer operations are completed, then the transfer to the memory macro 10 terminates.

The indicator bit monitor circuit 26 of FIG. 14 has the following function. When the Enable bit in the data (Fuse 2) transferred from the second fuse and fuse latch 23b is programmed with 1, the function extracts the ten-bits data other than the three-bit composed indicator bits and transfers the data to the data transfer control circuit 25 for being used as substitute data for the data of the first-operation dedicated Fuseset indicated by the three-bit composed indicator bits.

Even in the memory of the present embodiment, although the fuse data are compressed, multiple fuse-data programming operations can be performed.

In the case where eight Segments are provided in the memory cell array 11 of FIG. 4, and eight redundancy word lines exist in units of one Segment, the number of fuse elements usable to compensate for at least three defective cells in the second operation is 39 (=13×3). Accordingly, compared with 283 fuse elements in the first embodiment, the number of fuse elements can be significantly reduced.

### Modification of Second Embodiment

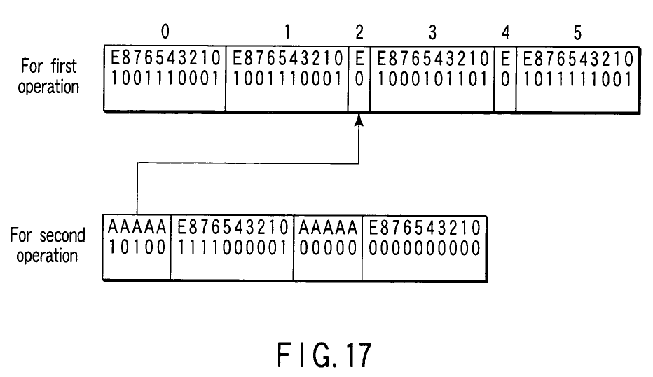

FIG. 17 shows exemplary redundancy information to be written into first and second fuse and fuse latches 23a and 23b in a memory of a modified embodiment of the second embodiment. Data to be written into the first fuse and fuse latch 23a are compressed by using a compression scheme similar to that used in the second embodiment.

In the second-operation dedicated second fuse and fuse latch 23b, one Fuseset is configured of 15 fuse elements. In the 15 fuse elements, five indicator bits are programmed into initial five fuse elements, and the Enable bit and address are programmed into the subsequent ten fuse elements.

In this case, unlike the case of the second embodiment, the indicator bits indicate the number of first-operation dedicated fuse elements from the top. In the example shown in FIG. 17, initial five indicator bits are “10100”. In this case, the indicator bits indicate that the address data written in the Fuseset is substituted for 20th or later data in the first-operation dedicated Fusesets.

A practical configuration of the fuse box 20 according to the modified embodiment is the same as that shown in FIG. 14 except for the algorithm used when new redundancy information is created in the data transfer control circuit 25.

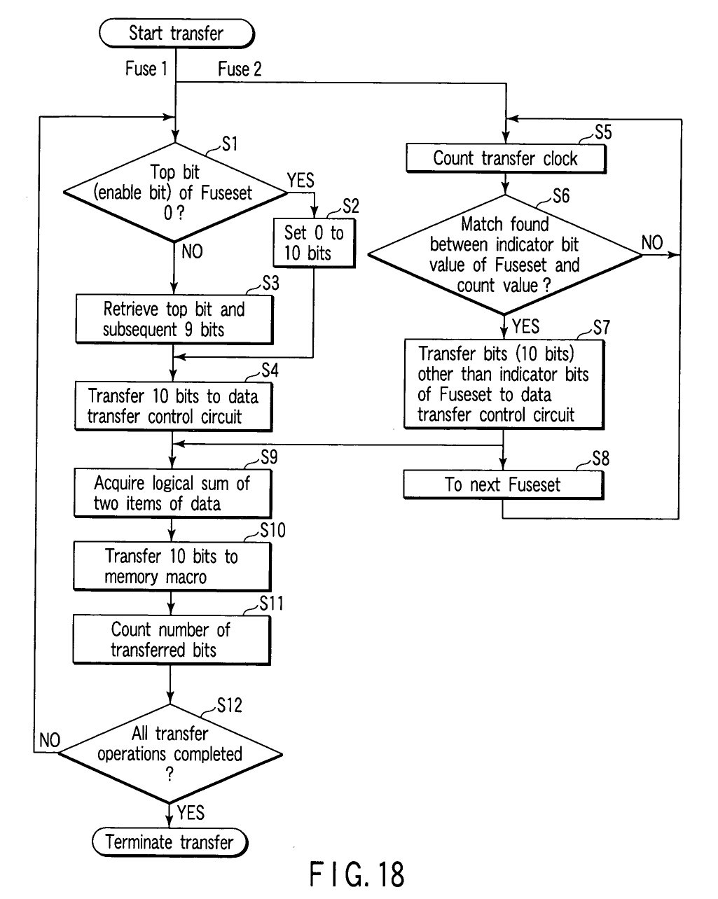

FIG. 18 is a flowchart showing an algorithm used when new redundancy information is created in the data transfer control circuit 25 of the memory of the modified embodiment. According to the algorithm, after start of data transfer, data programmed into the compressed state in the plurality of fuse elements for each of the first and second operations are expanded and concurrently subjected to transfer processing, logical sums of two items of data are acquired during the transfer and combined into new data, and the data are supplied to the memory macro 10.

First, after the start of transfer, the algorithm determines whether or not the top, i.e., Enable bit, of data (Fuse 1) transferred from the first fuse and fuse latch 23a is 0 (Step S1). If the Enable bit is 0, then ten-0-bits data are generated (Step S2). If the Enable bit is 1, then a first bit and nine bits subsequent thereto are retrieved (Step S3). In this manner, compressed data written in the first fuse and fuse latch 23a are expanded, and the expanded ten-bits data are transferred to the data transfer control circuit 25 (Step S4).

On the other hand, after the start of transfer, a transfer clock is counted (Step S5). Then, it is determined whether or not a match is found between a transfer-clock count result and a value of indicator bits of data (Fuse 2) transferred from the second fuse and fuse latch 23b (Step S6). As a consequence, if a match is not found, then the algorithm returns to Step S5, whereat the transfer clock is again counted. If a match is found, then ten-bits data, i.e., data other than the indicator bits, are transferred to the data transfer control circuit 25 (Step S7). For a comparison between a subsequent count value and indicator bits, indicator bits of a subsequent data (Fuse 2) are referenced (Step S8). That is, indicator bits of the second-operation dedicated second fuse and fuse latch 23b are referenced sequentially from the top.

Subsequently, the logical sum of the ten-bits data transferred at Step S4 and the ten-bits data transferred at Step S7 is acquired in units of the bit, whereby the data are combined into new redundancy information (Step S9) and transferred to the memory macro 10 (Step S10). Then, the number of the transferred bits is counted (Step S11), and it is determined whether or not all transfer operations are completed (Step S12). If all the transfer operations are not yet completed, then the algorithm returns to Steps S1 and S5. If all the transfer operations are completed, then the transfer to the memory macro 10 terminates.

The indicator bit monitor circuit 26 according to the present modified embodiment has the following function. When the Enable bit in the data (Fuse 2) transferred from the second fuse and fuse latch 23b is programmed with 1, the ten-bits data other than the five indicator bits are extracted and transferred to the data transfer control circuit 25 for being used as substitute data for the data of the first-operation dedicated Fuseset indicated by the five indicator bits.

Even in the memory of the present embodiment, although the fuse data are compressed, multiple fuse-data programming operations can be performed.

In the case where eight Segments are provided in the memory cell array 11 of FIG. 4, and eight redundancy word lines exist in units of one Segment, the number of fuse elements usable to compensate for at least three defective cells in the second operation is 45 (=15×3). Accordingly, compared with 39 fuse elements in the second embodiment, the number of fuse elements can be significantly reduced.

### Third Embodiment

The memory of each of the first and second embodiment and modified embodiment of the second embodiment has been described to the case where the compressed data is written into the first fuse and fuse latch 23a for being used in the first programming operation. However, the configuration may be such that noncompressed data is written into the first fuse and fuse latch 23a.

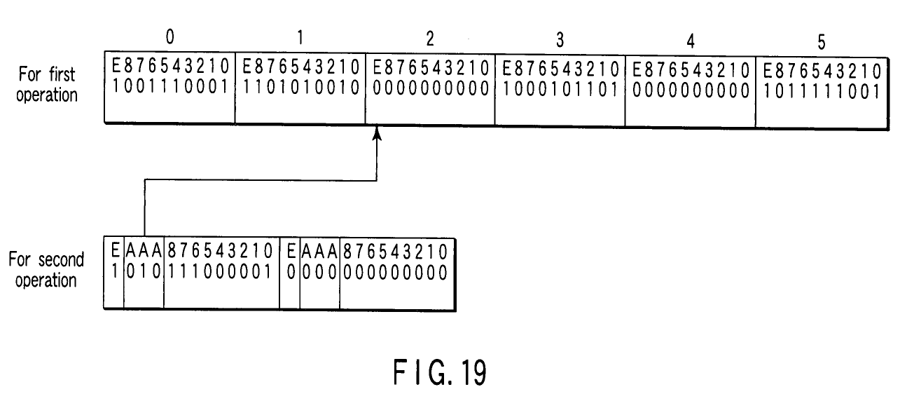

FIG. 19 shows exemplary redundancy information to be written into first, second fuse and fuse latches 23a, 23b in a memory of a third embodiment. Data to be written into the first fuse and fuse latch 23a is not compressed. More specifically, each one of Fusesets is configured of ten fuse elements, and ten-0-bits data are programmed as they are into the ten fuse elements not programmed with a row-redundancy address.

In the present embodiment, data compressed by a compression scheme similar to that used in the second embodiment is written into the second-operation dedicated second fuse and fuse latch 23b. That is, one Fuseset is configured of 13 fuse elements. In the 13 fuse elements, three-bit composed indicator bits are programmed into three fuse elements subsequent to the top-positioned Enable fuse (E) of these 13 fuse elements. The indicator bits are used to provide data indicating that data being intended to be programmed into the Fuseset is substituted for which one of first-operation dedicated Fusesets.

In the example shown in FIG. 19, three-bit composed indicator bits in data programmed into 13 fuse elements of the first Fuseset for the second operation are “010”. In this case, the indicator bits indicate that the data is substituted for the second data in the first-operation dedicated Fusesets.

A practical configuration of the fuse box 20 according to the third embodiment is the same as that shown in FIG. 14 except for the algorithm used when new redundancy information is created in the data transfer control circuit 25.

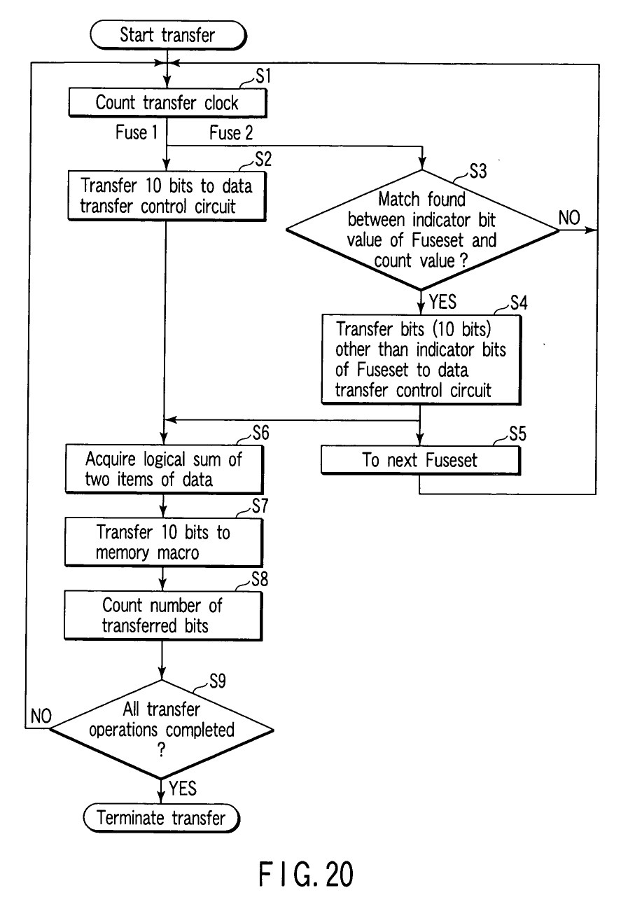

FIG. 20 is a flowchart showing an algorithm used when new redundancy information is created in the data transfer control circuit 25 of the memory of the third embodiment. According to the algorithm, after start of data transfer, data programmed into the plurality of fuse elements for the first operation is serially read as it is and is transferred. In addition, compressed data programmed into the plurality of fuse elements for the second operation is expanded and concurrently subjected to transfer processing, logical sums of two items of data are acquired during the transfer and combined into new data, and the data are supplied to the memory macro 10.

First, after start of transfer, a transfer clock is counted (Step S1). Data (Fuse 1) is serially transferred to the data transfer control circuit 25 from the first fuse and fuse latch 23a (Step S2). Then, it is determined whether or not a match is found between a transfer-clock count result and a value of indicator bits of data (Fuse 2) transferred from the second fuse and fuse latch 23b (Step S3). As a consequence, if a match is not found, then Steps S1 and S3 are iteratively executed. If a match is found, then ten-bits data, i.e., data other than the indicator bits, are transferred to the data transfer control circuit 25 (Step S4). In this manner, compressed data written in the first fuse and fuse latch 23b are expanded. For a comparison between a subsequent count value and indicator bits, indicator bits of a subsequent data (Fuse 2) are referenced (Step S5). That is, indicator bits of the second-operation dedicated second fuse and fuse latch 23b are referenced sequentially from the top.

Subsequently, the logical sum of the ten-bits data transferred at Step S2 and the ten-bits data transferred at Step S4 is acquired for each bit, whereby the data are combined into new redundancy information (Step S6) and transferred to the memory macro 10 (Step S7). Then, the number of the transferred bits is counted (Step S8), and it is determined whether or not all transfer operations are completed (Step S9). If all the transfer operations are not yet completed, then the algorithm returns to Step S1. If all the transfer operations are completed, then the transfer to the memory macro 10 terminates.

Even in the memory of the present embodiment, although the fuse data are compressed, multiple fuse-data programming operations can be performed.

Similarly as in the memory of the second embodiment, the number of fuse elements usable to compensate for at least three defective cells in the second operation is 39. Accordingly, compared with the fuse elements in the first embodiment, the number of fuse elements can be significantly reduced.

The memory of the present embodiment has been described with reference to the case where the data compressed by the scheme similar to that used in the second embodiment is written into the second-operation dedicated second fuse and fuse latch 23b. However, either data compressed by a compression scheme similar to that used in the case of the memory of the first embodiment or data compressed by a compression scheme similar to that used in the case of the memory of the second embodiment may be written into the second-operation dedicated second fuse and fuse latch 23b.

### Fourth Embodiment

The compression efficiency is apparently reduced when compressing data composed of a specific number of consecutive 0s into a single-0-bit data as in the case of, for example, the first embodiment wherein one of a plurality of redundancy information storage circuits has a plurality of Fusesets different in the number of fuse elements. This case corresponds to, for example, a case where Fusesets different in the number of fuse elements depending on the operations of row redundancy and column redundancy. A case is now contemplated in which cases where a single Fuseset is configured of ten fuse elements and eight fuse elements are mixed or combined. With the scheme of compressing data composed of all the ten 0 bits into single-0-bit data being employed, data composed of all eight bits of data 0 are not compressed.

As such, in a memory of a fourth embodiment, both the scheme of compressing the all-ten-0-bits data into the single-0-bit data and the scheme of compressing all-eight-0-bits data into the single-0-bit data are employed in combination. Relevant expansion schemes to be used in the event of data expansion are arranged switchable from each other so as to be adaptable even to the case where one of the plurality of redundancy information storage circuits contains the plurality of Fusesets different in the number of fuse elements.

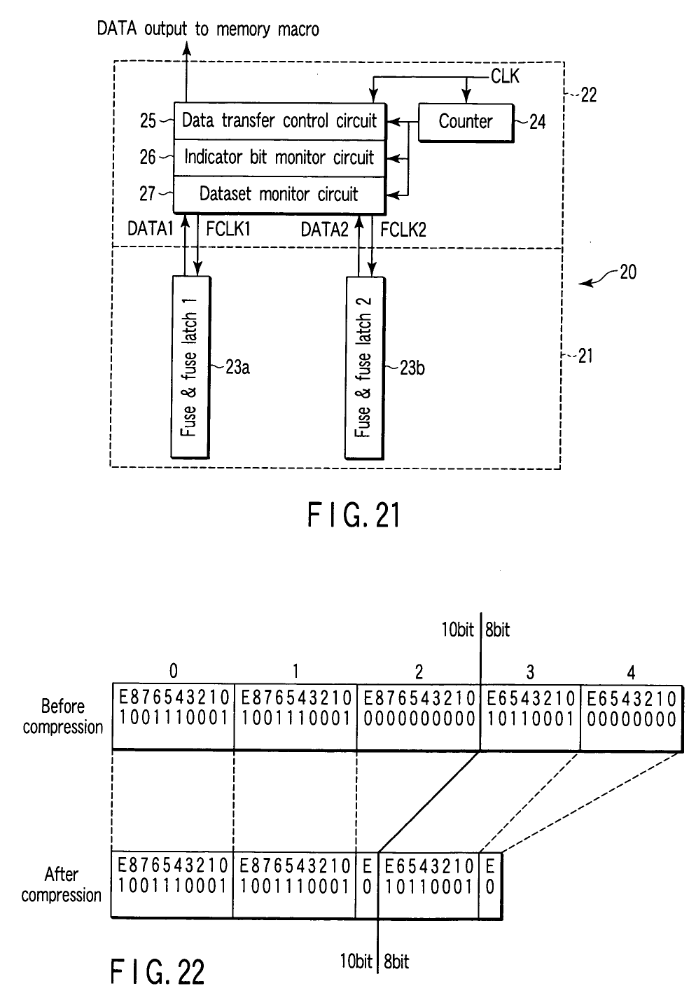

FIG. 21 is a block diagram showing a practical configuration of a fuse box 20 in the memory of the fourth embodiment. Similarly as in the case shown in FIG. 14, first and second fuse and fuse latches 23a and 23b are provided as examples of the plurality of fuse and fuse latches in a fuse and fuse latch 21.

In the fuse data transfer control circuit 22, a dataset monitor circuit 27 is provided in addition to the counter 24 and the data transfer control circuit 25. The dataset monitor circuit 27 monitors the count output of the counter 24 and performs detection of whether pre-compression data is ten bits of data or eight bits of data. The detection result is supplied to the data transfer control circuit 25.

FIG. 22 is a view showing exemplary redundancy information before being written into the first fuse and fuse latch 23a, that is, pre-compression redundancy information, and exemplary redundancy information after having been written thereinto, that is, post-compression redundancy information, in the memory of the fourth embodiment. In this case, for example, redundancy information for row redundancy is composed of ten bits, and redundancy information for column redundancy is composed of eight bits. Pre-compression row-redundancy ten-bits data are composed of a one-bit Enable bit (E) and a nine-bit row address. Pre-compression column-redundancy eight bits of data are composed of a one-bit Enable bit (E) and a seven-bits column address.

The all-ten-0-bits data and the all-eight-0-bits data are individually compressed into the single-0-bit data by using compression schemes different from each other, and the data are written into the first fuse and fuse latch 23a.

A compression scheme for the redundancy information to be written into the second fuse and fuse latch 23b is not specifically limited. As such, a compression scheme similar to any one of those employed in the first to third embodiments may be employed. The indicator bit monitor circuit 26 shown in FIG. 21 becomes necessary in the case where a compression scheme similar to that employed in the second embodiment is employed as a compression scheme for the redundancy information being written into the second fuse and fuse latch 23b. Consequently, in the case of a compression scheme other than a compression scheme similar to that employed in the second embodiment, the indicator bit monitor circuit 26 can be omitted.

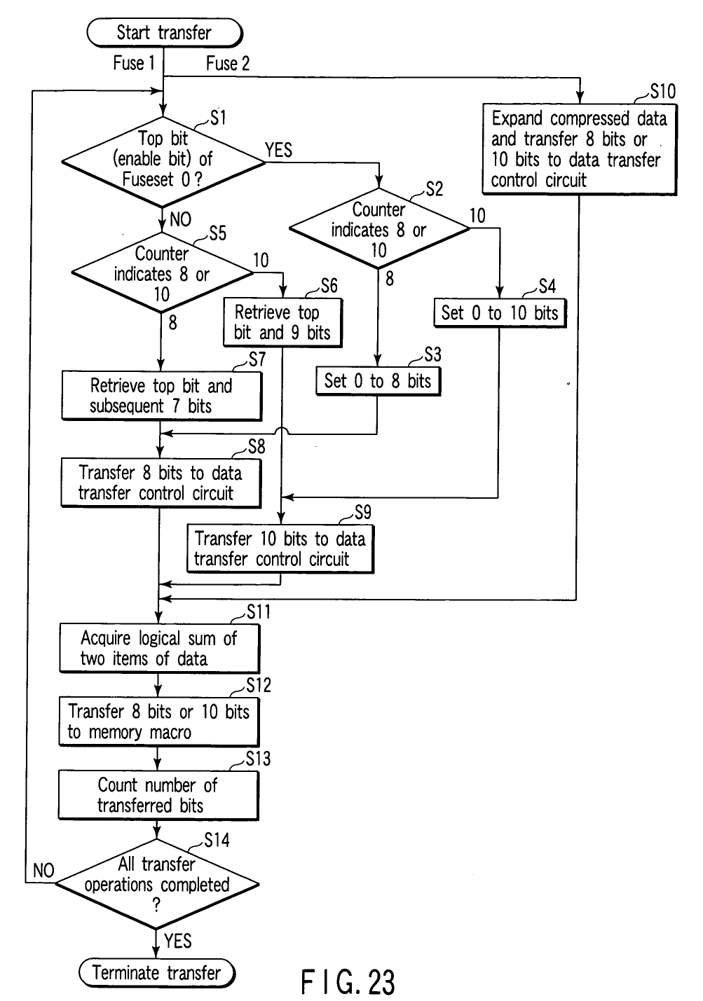

FIG. 23 is a flowchart showing an algorithm in the event that compressed redundancy information is expanded in the data transfer control circuit 25 of FIG. 21 and transferred to the memory macro 10.

First, after start of transfer, the algorithm determines whether or not the top, i.e., Enable bit, of data (Fuse 1) transferred from the first fuse and fuse latch 23a is 0 (Step S1). If the Enable bit is 0, then the count contents of the counter 24 is referenced, and it is then determined whether the indication of the counter represents eight bits or ten bits (Step S2). If the counter indication represents eight bits, then data composed of eight bits representing consecutive 0s are generated (Step S3). If the counter indication represents ten bits, then data composed of ten bits representing consecutive 0s are generated (Step S4).

On the other hand, if the Enable bit is determined to be 1, then the count contents of the counter 24 is referenced, and it is then determined whether the counter indication represents eight bits or ten bits (Step S5). If the counter indication represents ten bits, then data of the top Enable bit and subsequent nine bits are retrieved (Step S6). If the counter indication represents eight bits, then data of the top Enable bit and subsequent seven bits are retrieved (Step S7). The eight-bits data or ten-bits data thus created are transferred to the data transfer control circuit 25 (Steps S8, S9).

On the other hand, the second fuse and fuse latch 23b is programmed with second-operation dedicated redundancy information. Data (Fuse 2) programmed into the second fuse and fuse latch 23b are expanded to eight-bits or ten-bits data by using an expansion scheme corresponding to the compression scheme applied therefor, and the data are transferred to the data transfer control circuit 25 (Step S10). The logical sum of the eight-bits data in the transferred data and the eight-bits data transferred at Step S8 is acquired in units of the bit, whereby the data are combined into new redundancy information (Step S11). On the other hand, the logical sum of the ten-bits data and the ten-bits data transferred at Step S9 is acquired in units of the bit, whereby the data are combined into new redundancy information (Step S11). The combined eight-bit or ten-bit data are transferred to the memory macro 10 (Step S12). Then, the number of the transferred bits is counted (Step S13), and it is determined whether or not all transfer operations are completed (Step S14). If all the transfer operations are not yet completed, the algorithm returns to Steps S1 and S10. If all the transfer operations are completed, the transfer to the memory macro 10 terminates.

Even in the memory of the present embodiment, although the fuse data are compressed, multiple fuse-data programming operations can be performed.

Further, according to the memory of the present embodiment, even when Fusesets different in the number of fuse elements depending on the operations of row redundancy and column redundancy, data compression operations can be individually implemented therefor.

### Fifth Embodiment

In a memory of a fifth embodiment, similarly as in the case of the memory of the fourth embodiment, both the scheme of compressing data such as all-ten-0-bits data into single-0-bit data and the scheme of compressing data such as all-eight-0-bits data into single-0-bit data are employed in combination. In addition, relevant expansion schemes to be used in the event of data expansion are switchable from each other so as to be adaptable even to the case where one of the plurality of redundancy information storage circuits contains the plurality of Fusesets different in the number of fuse elements.

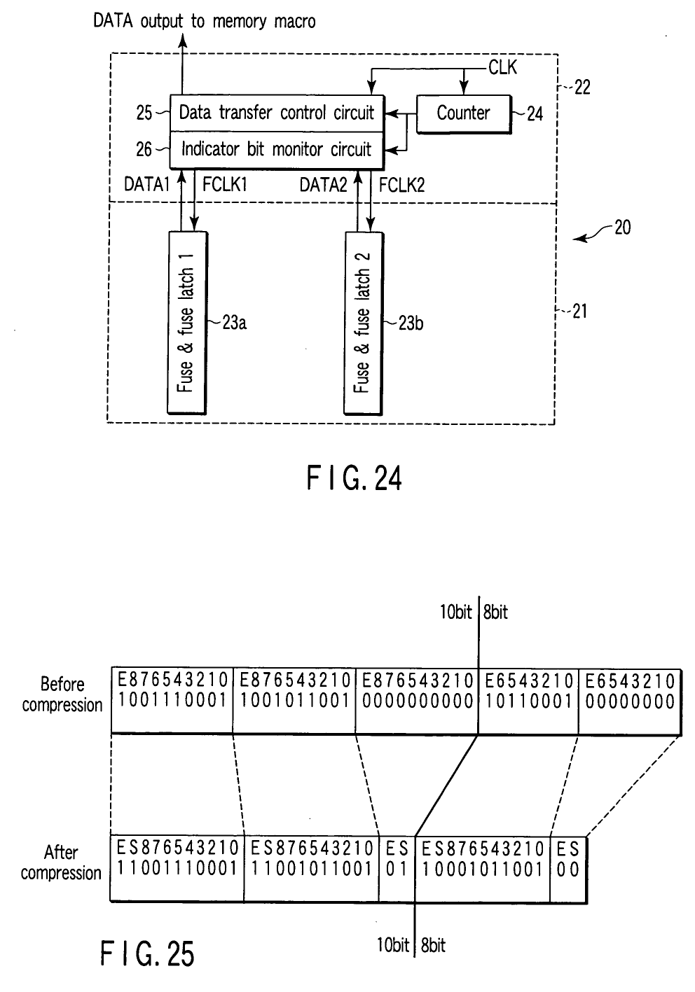

FIG. 24 is a block diagram showing a practical configuration of a fuse box 20 in the memory of the fifth embodiment. Similarly as in the case shown in FIG. 14, first and second fuse and fuse latches 23a and 23b are provided as examples of the plurality of fuse and fuse latches in a fuse and fuse latch 21.

In the fuse data transfer control circuit 22, a counter 24, data transfer control circuit 25, and indicator bit monitor circuit 26 are provided. The indicator bit monitor circuit 26 has the function of monitoring an indicator-bit value, detecting whether pre-compression data is ten-bits or eight-bits data, and supplying the detection result to the data transfer control circuit 25.

FIG. 25 is a view showing exemplary redundancy information before being written into the first fuse and fuse latch 23a, that is, pre-compression redundancy information, and exemplary redundancy information after having been written thereinto, that is, post-compression redundancy information, in the memory of the fifth embodiment. In this case, for example, redundancy information for row redundancy is composed of ten bits, and redundancy information for column redundancy is composed of eight bits. Pre-compression row-redundancy ten-bits data are composed of a one-bit Enable bit (E) and a nine-bit row address. Pre-compression column-redundancy eight bits of data are composed of a one-bit Enable bit (E) and a seven-bits column address.

The all-ten-0-bits data and the all-eight-0-bits data are individually compressed into the single-0-bit data by using compression schemes different from each other. After data compression, one-bit composed indicator bit (S) is added subsequent to the top-positioned Enable fuse (E). In the present embodiment, the indicator bit (S) having the 1 value indicates that the pre-compression data is composed of ten bits, and the indicator bit (S) having the 0 value indicates that the pre-compression data is composed of eight bits.

In this case also, a compression scheme for the redundancy information to be written into the second fuse and fuse latch 23b is not specifically limited. As such, a compression scheme similar to any one of those employed in the first to third embodiments may be employed. In the case where a compression scheme similar to that employed in the second embodiment is employed as a compression scheme for redundancy information being written into the second fuse and fuse latch 23b, the indicator bit monitor circuit 26 shown in FIG. 24 is used as well to expand the redundancy information written into the second fuse and fuse latch 23b.

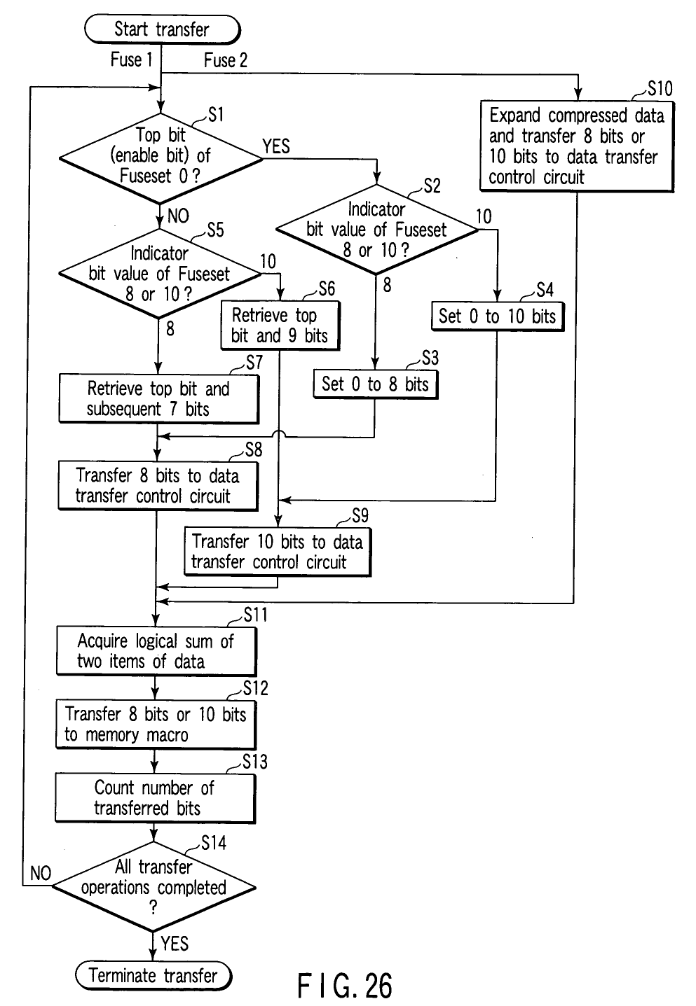

FIG. 26 is a flowchart showing an algorithm in the event that compressed redundancy information is expanded in the data transfer control circuit 25 of FIG. 24 and transferred to the memory macro 10.

First, after start of transfer, the algorithm determines whether or not the top, i.e., Enable bit, of data (Fuse 1) transferred from the first fuse and fuse latch 23a is 0 (Step S1). If the Enable bit is 0, then the indicator-bit value is determined (Step S2). If the indicator bit is 0 indicating eight bits, then 0-string eight-bits data are generated (Step S3). If the indication value is 1 indicating ten bits, then 0-string ten-bits data are generated (Step S4).

On the other hand, if the Enable bit is determined to be 1 at Step S1, then it is determined whether or not the indicator bit is 0 (Step S5). If the indicator bit is 1 indicating ten bits, then data of nine bits subsequent to the indicator bit are retrieved (Step S6). If the indicator bit is 0 indicating eight bits, then data of seven bits subsequent to the indicator bit are retrieved (Step S7). The eight-bits data or ten-bits data thus created are transferred to the data transfer control circuit 25 (Steps S8, S9).

On the other hand, the second fuse and fuse latch 23b is programmed with second-operation dedicated redundancy information. Data (Fuse 2) programmed into the second fuse and fuse latch 23b are expanded to eight-bit or ten-bit data by using an expansion scheme corresponding to the compression scheme applied therefor, and the data are transferred to the data transfer control circuit 25 (Step S10). The logical sum of the eight-bits data in the transferred data and the eight-bits data transferred at Step S8 is acquired in units of the bit, whereby the data are combined into new redundancy information (Step S11). On the other hand, the logical sum of the ten-bits data and the ten-bits data transferred at Step S9 is acquired in units of the bit, whereby the data are combined into new redundancy information (Step S11). The combined eight-bit or ten-bit data are transferred to the memory macro 10 (Step S12). Then, the number of the transferred bits is counted (Step S13), and it is determined whether or not all transfer operations are completed (Step S14). If all the transfer operations are not yet completed, the algorithm returns to Steps S1 and S10. If all the transfer operations are completed, the transfer to the memory macro 10 terminates.

Even in the memory of the present embodiment, although the fuse data are compressed, multiple fuse-data programming operations can be performed.

Further, according to the memory of the present embodiment, even when Fusesets different in the number of fuse elements are used depending on the operations of row redundancy and column redundancy, data compression operations can be individually implemented therefor.

In the memory of the present embodiment, since the Fuseset contains the one-bit composed indicator bit, the number of fuse elements has to be increased, in comparison to the memory of the fourth embodiment. Nevertheless, however, since the compression scheme for the Fuseset is know from the indicator-bit value, it is advantageous, particularly, in such a case where data representing the compression schemes for the Fusesets are intermittently arranged in the first fuse and fuse latch 23a. In comparison, in the memory of the fourth embodiment, it is rather advantageous for expansion efficiency in the case where, as shown in FIG. 22, the Fusesets different in the number of fuse elements are collectively disposed.

### Sixth Embodiment

In the memory of the type according to the above-described second embodiment or the modified embodiment thereof, the plurality of Fusesets are serially aligned in the second-operation dedicated second fuse and fuse latch 23b in accordance with the order of transfer operations to the fuse latches 15, 16 from fuse data transfer control circuit 22. As such, when fuse elements are once blown, data (address) appearing before the turn of the Fuseset cannot be programmed.

A memory of a sixth embodiment is rendered to enable the second address programming to be performed in an arbitrary order.

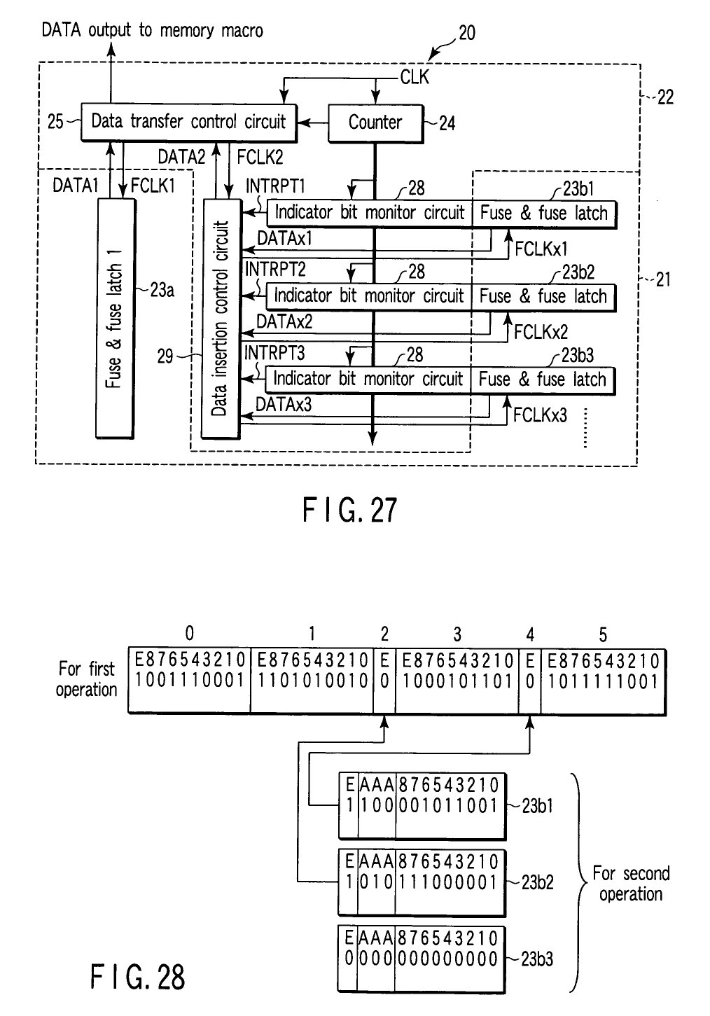

FIG. 27 is a block diagram showing a practical configuration of a fuse box 20 in the memory of the sixth embodiment. A first-programming first fuse and fuse latch 23a, and a plurality of second-programming second fuse and fuse latches 23b1, 23b2, 23b3, etc. each allowing one redundancy address to be programmed are provided as examples of the plurality of fuse and fuse latches in the fuse and fuse latch 21.

In the fuse data transfer control circuit 22, a plurality of indicator-bit monitoring circuits 28 disposed corresponding to the second fuse and fuse latches 23bi (23b1, 23b2, 23b3, etc.), and a data insertion control circuit 29 are provided in addition to the counter 24 and the data transfer control circuit 25.

The plurality of indicator-bit monitoring circuits 28 each detect the value of indicator bits written into the corresponding second fuse and fuse latches 23b1, 23b2, 23b3, etc. In addition, when the Enable bit is 1, the plurality of indicator-bit monitoring circuits 28 each perform a comparison between the value of the counter 24 and the indicator-bit value. If a match is found in the comparison, and the respective indicator-bit monitoring circuit 28 supplies an interrupt signal INTRPTi (INTRPT1, INTRPT2, INTRPT3, etc.) to the data insertion control circuit 29. Upon reception of the match signal, the data insertion control circuit 29 supplies a clock signal FCLKxi (FCLKx1, FCLKx2, FCLKx3, etc.) to a second fuse and fuse latch corresponding to the match between the value of the counter 24 and the indicator-bit value, retrieves ten-bits data DATAxi (DATAx1, DATAx2, DATAx3, etc.) from the second fuse and fuse latch, and supplies the data to the data transfer control circuit 25.

FIG. 28 is a view showing exemplary redundancy information to be written into each of the first fuse and fuse latch 23a and three second fuse and fuse latches 23b1, 23b2, and 23b3 in the case where the three second fuse and fuse latches 23b1, 23b2, and 23b3 are provided as the second-operation dedicated second fuse and fuse latches 23b.

Data to be written into the first fuse and fuse latch 23a are compressed by using a compression scheme similar to that used in the second embodiment. That is, ten-0-bits data are compressed into single-0-bit data. The second fuse and fuse latches 23b1, 23b2, and 23b3 are each configured of one Fuseset including 13 fuse elements. The Enable fuse (E) is programmed in the top of each of the respective Fuseset, the three-bit composed indicator bit (A) into three fuse elements subsequent thereto, and an address is programmed into the remaining nine fuse elements. The three-bit composed indicator bits are used to indicate the position in post-combination data into which data (address) programmed into the corresponding Fuseset is to be inserted.

In the example shown in FIG. 28, the indicator bits of the second-operation second fuse and fuse latch 23b1 are “100”. In this case, the indicator bits indicate that the nine-bits data (address) are to be inserted into the fourth data position.

Similarly, the indicator bits of the second-operation second fuse and fuse latch 23b2 are 010. In this case, the indicator bits indicate that the nine-bits data (address) are to be inserted into the second data position.

The Fuseset of the second-operation second fuse and fuse latch 23b3 is not programmed and is unused.

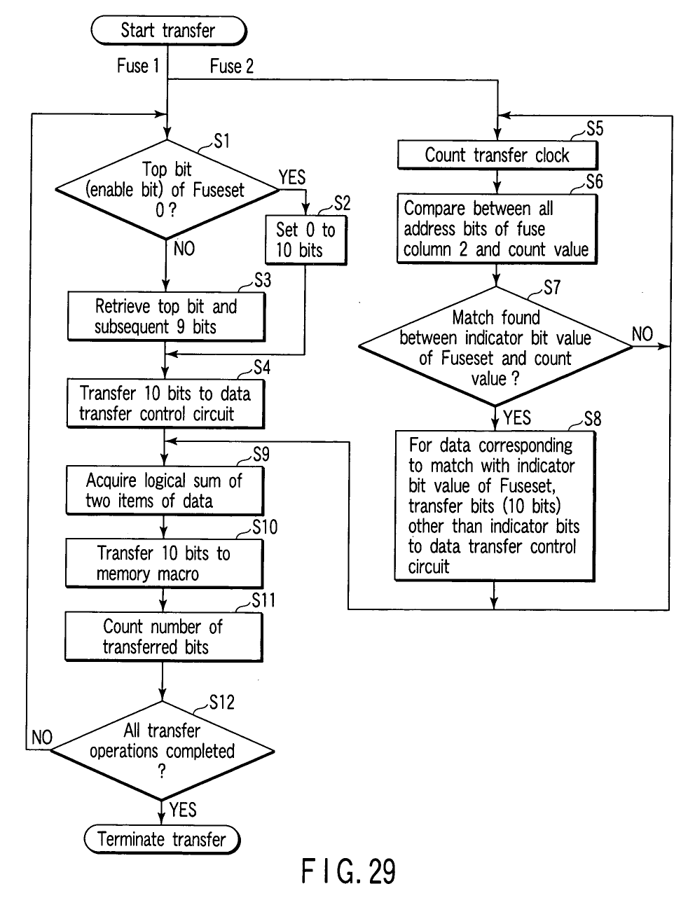

FIG. 29 is a flowchart showing an algorithm used when new redundancy information is created in the data transfer control circuit 25 in the memory of the sixth embodiment. According to the algorithm, after start of data transfer, compressed data programmed in the plurality of first-operation dedicated fuse elements are expanded and concurrently undergoes transfer processing, logical sums of the data and the plurality of second-operation dedicated fuse elements are acquired during the transfer and combined into new data, and the data are supplied to the memory macro 10.

First, after the start of transfer, the algorithm determines whether or not the top, i.e., Enable bit, of data (Fuse 1) transferred from the first fuse and fuse latch 23a is 0 (Step S1). If the Enable bit is 0, then ten-0-bits data is generated (Step S2). If the Enable bit is 1, then a first bit and nine bits subsequent thereto are retrieved (Step S3). In this manner, compressed data written in the first fuse and fuse latch 23a are expanded and ten-bits data are generated, and the generated ten-bits data are transferred to the data transfer control circuit 25 (Step S4).

On the other hand, after the start of transfer, a transfer clock is counted (Step S5). Then, it is compared between a transfer-clock count value and values of indicator bits written in all the second fuse and fuse latches 23bi (Step S6). Then, it is determined whether or not a match is found between the transfer-clock count value and the indicator-bit values written in all the second fuse and fuse latches 23bi (Step S7). As a consequence, if a match is found, then ten-bits data, i.e., data other than the indicator bits, are transferred to the data transfer control circuit 25 (Step S8). On the other hand, if a match is not found, then the algorithm returns to Step S5, whereat the transfer clock is again counted.

Subsequently, the logical sum of the ten-bits data transferred at Step S4 and the ten-bits data transferred at Step S8 is acquired in units of the bit, whereby the data are combined into new redundancy information (Step S9) and transferred to the memory macro 10 (Step S10). Then, the number of the transferred bits is counted (Step S11), and it is determined whether or not all transfer operations are completed (Step S12). If all the transfer operations are not yet completed, then the algorithm returns to Steps S1 and S5. If all the transfer operations are completed, then the transfer to the memory macro 10 terminates.

Even in the memory of the sixth embodiment, although the fuse data are compressed, multiple fuse-data programming operations can be performed.

Further, in the memory of the present embodiment, the plurality of mutually independent Fusesets are provided for the second-operation dedicated fuse and fuse latches. The data-insertion dedicated indicator bits are programmed into the respective Fuseset, comparison is performed between the indicator bits and the count value in units of the data-transfer operation, and the data (address) to be programmed into the Fuseset is inserted when a match is found in the comparison. Accordingly, within the range of the number of prepared Fusesets, a desired number of fuse blowing operations can be performed without selecting data insertion positions.

### Modification of Sixth Embodiment

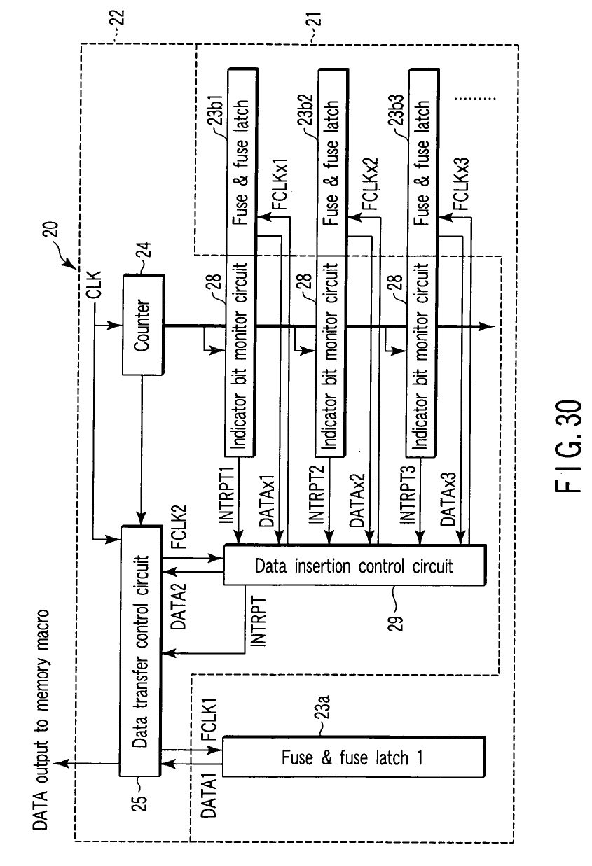

FIG. 30 is a block diagram showing a practical configuration of a fuse box 20 in a memory of a modified embodiment of the sixth embodiment.

The memory of the sixth embodiment shown in FIG. 27 has been described to the following case. The data insertion control circuit 29 supplies the clock signal FCLKxi to the second fuse and fuse latch 23bi corresponding to the match between the value of the counter 24 and the indicator-bit value, retrieves ten-bits data DATAxi from that second fuse and fuse latch, and supplies the data to the data transfer control circuit 25. The data transfer control circuit 25 in turn supplies the transfer-dedicated clock signal FCLK2 to the data insertion control circuit 29.

In comparison, in the memory of the modified embodiment, upon reception of an interrupt signal INTRPTi from the indicator-bit monitoring circuit 28, the data insertion control circuit 29 outputs an interrupt signal INTRPT to the data transfer control circuit 25. Upon reception of the interrupt signal INTRPT, the data transfer control circuit 25 supplies a transfer-dedicated clock signal FCLK2 to the data insertion control circuit 29.

Upon reception of the clock signal FCLK2, the data insertion control circuit 29 supplies an clock signal FCLKxi to the second fuse and fuse latches 23bi corresponding to the indicator-bit monitoring circuit 28 that has output the interrupt signal INTRPTi. In this event, the data insertion control circuit 29 receives DATAxi output from the second fuse and fuse latches 23bi, and in turn supplies the data as data DATA2 to the data transfer control circuit 25.

When the interrupt signal INTRPT is supplied, the data supplied from the data transfer control circuit 25 to the memory macro 10 is data stored in the second fuse and fuse latches 23bi. In this event, also the data DATA1 stored in the first fuse and fuse latch 23a is continually supplied to the data transfer control circuit 25 without being stopped. That is, the clock signal FCLK1 is all time supplied to the first fuse and fuse latch 23a, and the data DATA1 is kept output from the first fuse and fuse latch 23a. In practice, the data transfer control circuit 25 acquires a logical sum of the data DATA1 and DATA2 supplied from the respective first and second fuse and fuse latches 23a and 23bi and outputs the resultant data to the memory macro 10. Alternatively, in accordance with the interrupt signal INTRPT, the data transfer control circuit 25 performs switching between two data lines, i.e., wires dedicated to transfer the data DATA1 and DATA2, thereby to output the data DATA1 or DATA2.

In the former case, that is, in the case where the logical sum of the two items of data is acquired, it is not permitted to perform fuse blowing in the first and second operations on the same redundancy word line (RWL). In the latter case, that is, in the case where switching is performed between the two items of data, fuse blowing in the second operation is all time preceded. A control circuit for performing these control operations is included in the data insertion control circuit 29.

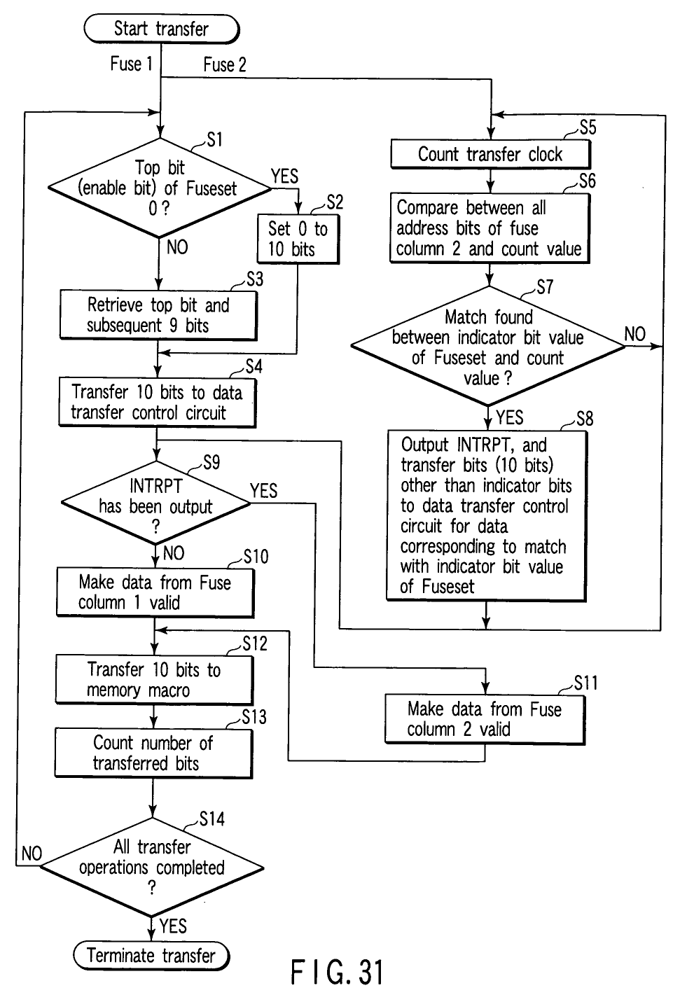

FIG. 31 is a flowchart showing an algorithm used when new redundancy information is created in the data transfer control circuit 25 of the memory of the modification of the sixth embodiment. According to the algorithm, after data transfer, data programmed in the compressed state in the plurality of fuse elements for the first operation are expanded and transferred to the data transfer control circuit. In parallel therewith, a match between indicator bits of data programmed in the plurality of second-operation dedicated fuse elements and count value is detected, and an interrupt signal INTRPT is generated when the match is found. Data to be transferred to the memory macro is selected in accordance with the interrupt signal INTRPT.

First, after the start of transfer, the algorithm determines whether or not the top, i.e., Enable bit, of data (Fuse 1) transferred from the first fuse and fuse latch 23a is 0 (Step S1). If the Enable bit is 0, then ten-0-bits data are generated (Step S2). If the Enable bit is 1, then a first bit and nine bits subsequent thereto are retrieved (Step S3). In this manner, compressed data written in the first fuse and fuse latch 23a are expanded and ten-bits data are generated, and the generated ten-bits data are transferred to the data transfer control circuit 25 (Step S4).

On the other hand, after the start of transfer, a transfer clock is counted (Step S5). Then, comparison is performed between the transfer-clock value and values of indicator bits written in all the second fuse and fuse latches 23bi (Step S6). Then, it is determined whether or not a match is found between the transfer-clock count value and the indicator-bit values written in all the second fuse and fuse latches 23bi (Step S7). As a consequence, if a match is found, then an interrupt signal INTRPT is output, ten-bits data other than the indicator bits of the data matching with the indicator bits are transferred to the data transfer control circuit 25 (Step S8). On the other hand, if a match is not found, then the algorithm returns to Step S5, whereat the transfer clock is again counted.

Subsequently, it is determined whether or not the interrupt signal INTRPT has been output (Step S9). If the interrupt signal INTRPT has not been output, data from a Fuse column 1 is selected as valid data (Step S10). On the other hand, if the interrupt signal INTRPT has been output, data from a Fuse column 2 is selected as valid data (Step S11). Then, the selected data is transferred to the memory macro 10 (Step S12). Subsequently, the number of the transferred bits is counted (Step S13), and it is determined whether or not all transfer operations are completed (Step S14). If all the transfer operations are not yet completed, then the algorithm returns to Steps S1 and S5. If all the transfer operations are completed, then the transfer to the memory macro 10 terminates.

Even in the memory of the modification of the sixth embodiment, although the fuse data are compressed, multiple fuse-data programming operations can be performed.

Further, in the memory of the present embodiment, the plurality of mutually independent Fusesets are provided for the second-operation dedicated fuse and fuse latches. The data-insertion dedicated indicator bits are programmed into the respective Fuseset, comparison is performed between the indicator bits and the count value in units of the data-transfer operation, and the data (address) to be programmed into the Fuseset is inserted when a match is found in the comparison. Accordingly, within the range of the number of prepared Fusesets, a desired number of fuse blowing operations can be performed without selecting data insertion positions.

Each of the embodiments and the modified embodiments thereof has been described to the exemplary case where eight redundancy word lines are prepared for 512 word lines. However, in a case where the number of the redundancy word lines is increased or reduced and further in the case with many banks (one bank refers to a combination of 512 word lines and eight redundancy word lines), the cases can be handled by changing the definitions of the indicator bit.

### Seventh Embodiment

A memory of a seventh embodiment will be described here. The memory of the second embodiment has been described to the case where the data compressed by the different compression schemes are individually programmed into the first and second fuse and fuse latches 23a and 23b for the first and second operations. In comparison thereto, the memory of the seventh embodiment is made such that data compressed by the same compression scheme are programmed into the first and second fuse and fuse latches 23a and 23b, thereby to improve the use efficiency of the fuse elements.

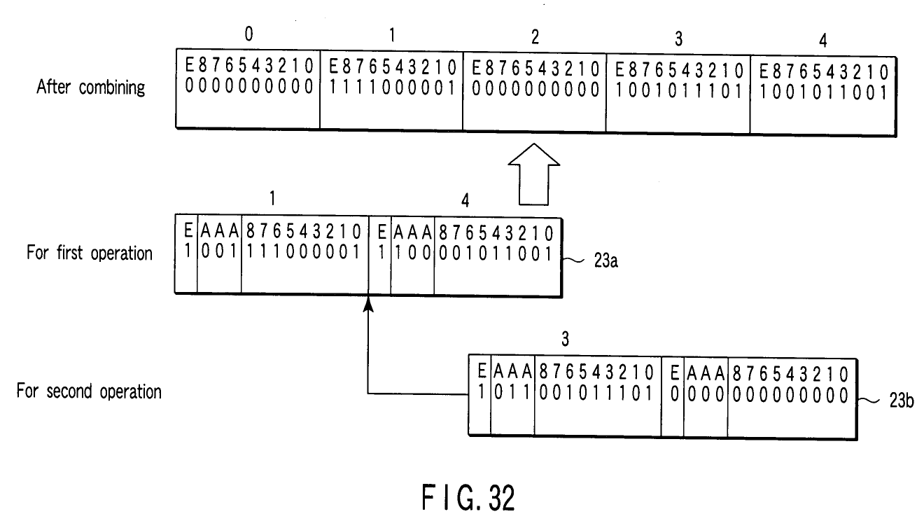

FIG. 32 is a view showing exemplary redundancy information to be written into the first, second fuse and fuse latches in the memory of the seventh embodiment. More specifically, in each of the first and second operations, single-bit data is programmed into the Enable fuse (E) in the first bit position, indicator bits are programmed into three indicator bits (A) subsequent thereto, and an address for specifying an address using the row redundancy is programmed into the remaining nine data bits (address bits). In the example shown in FIG. 32, three-bit composed indicator bits of one Fuseset in the second-operation dedicated second fuse and fuse latch 23b being used for programming are 011. In this case, indicator bits indicate that nine-bits data (address) subsequent to the indicator bits are inserted in the third position after compression.

A fuse box 20 in the memory of the present embodiment has a configuration similar to that of FIG. 14.

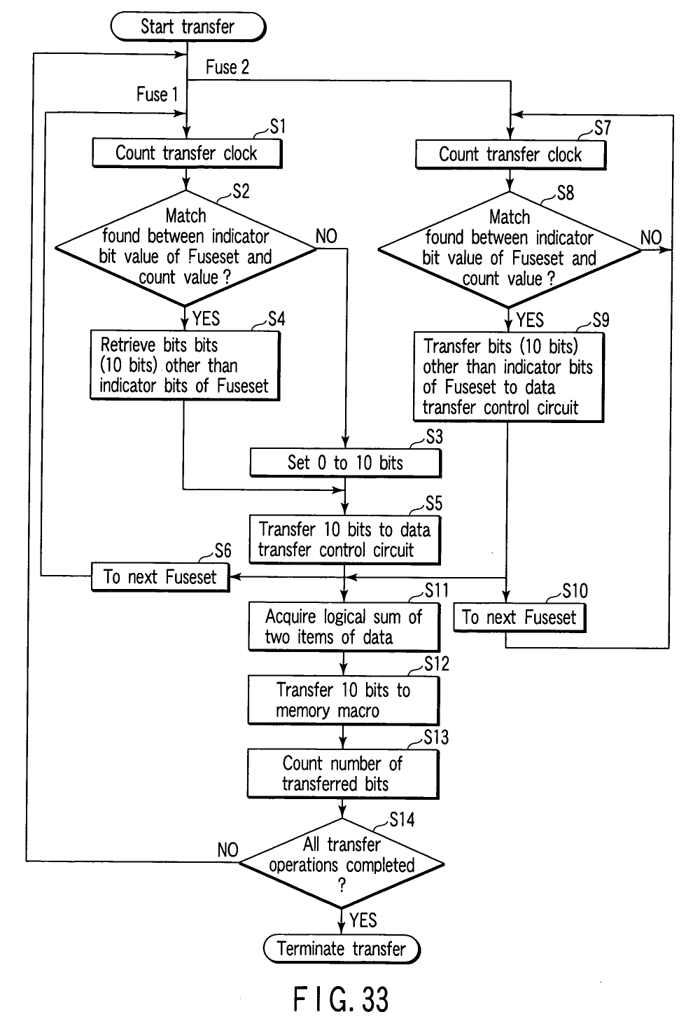

FIG. 33 is a flowchart showing an algorithm used when new redundancy information is created in a data transfer control circuit 25 in the memory of the seventh embodiment. According to the algorithm, after start of data transfer, compressed data programmed into a plurality of first-operation dedicated fuse elements are expanded and concurrently subjected to transfer processing, logical sums of the data and data programmed in the plurality of second-operation dedicated fuse elements are acquired during the transfer and combined into new data, and the data are supplied to the memory macro 10.

First, after the start of data transfer from the first fuse and fuse latch 23a, a transfer clock is counted (Step S1). Then, it is determined whether or not a match is found between a transfer-clock count value and a value of indicator bits programmed in the first fuse and fuse latch 23a (Step S2). As a consequence, if a match is not found, then ten-0-bits data are generated (Step S3). On the other hand, if a match is found, then ten-bits data, i.e., data other than the indicator bits, are retrieved (Step S4). Then, the ten-bits data generated as described above are transferred to the data transfer control circuit 25 (Step S5). For a comparison between a subsequent count value and indicator bits, indicator bits of a subsequent data (Fuse 1) are referenced (Step S6). That is, indicator bits of the first-operation dedicated first fuse and fuse latch 23a are referenced sequentially from the top.

Also, after start of data transfer from the second fuse and fuse latch 23b, a transfer clock is counted (Step S7). Then, it is determined whether or not a match is found between a transfer-clock count value and a value of indicator bits programmed in the second fuse and fuse latch 23b (Step S8). As a consequence, if a match is found, then ten-bits data, i.e., data other than the indicator bits, are transferred to the data transfer control circuit 25 (Step S9). For a comparison between a subsequent count value and indicator bits, indicator bits of a subsequent data (Fuse 2) are referenced (Step S10). That is, indicator bits of the second-operation dedicated second fuse and fuse latch 23b are referenced sequentially from the top.

On the other hand, the logical sum of the ten-bits data transferred at Step S5 and the ten-bits data transferred at Step S9, whereby the data are combined into new redundancy information (Step S11) and transferred to the memory macro 10 (Step S12). Then, the number of the transferred bits is counted (Step S13), and it is determined whether or not all transfer operations are completed (Step S14). If all the transfer operations are not yet completed, then the algorithm returns to Steps S1 and S7. If all the transfer operations are completed, then the transfer to the memory macro 10 terminates.

Even in the memory of the present embodiment, although the fuse data are compressed, multiple fuse-data programming operations can be performed.

Further, in the memory of the present embodiment, similarly as in the case of the sixth embodiment, the plurality of mutually independent Fusesets are provided for the second-operation dedicated fuse and fuse latches. Accordingly, fuse blowing can performed without selecting data insertion positions.

### Eighth Embodiment

With such memories as those of the sixth embodiment and modified embodiment, inconveniences as described hereinbelow can occur depending on the case.

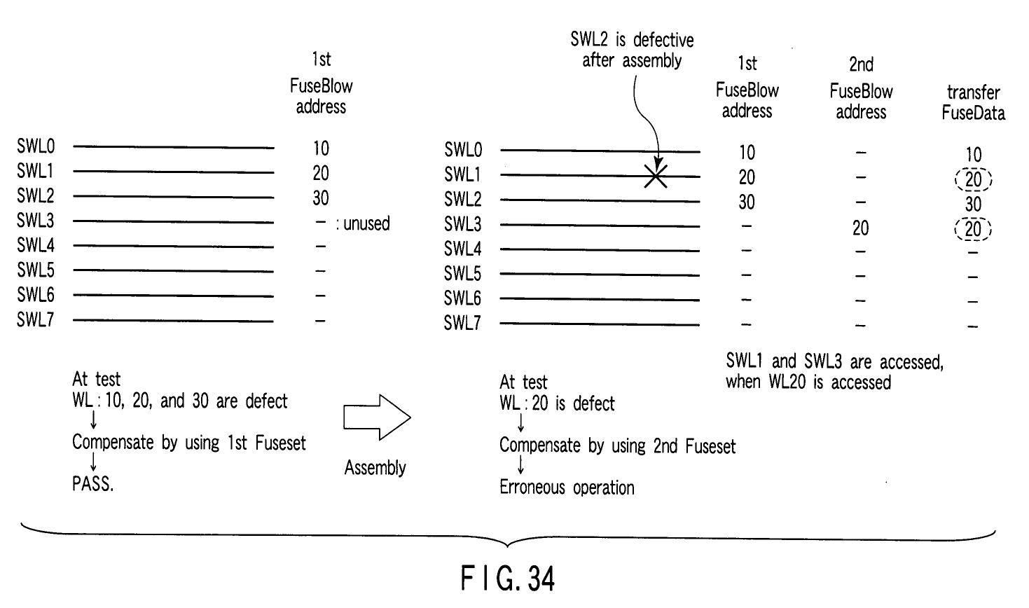

FIG. 34 shows eight redundancy word lines RWL1 to RWL7 provided for 512 word lines WL, address values (1st and 2nd Fuse Blow addresses) to be programmed into first- and second-operation dedicated Fusesets, and address values (transfer Fuse Data) to be actually transferred into the memory macro 10 in each of the memories of the six embodiment and the modified example thereof.

In the case where an address value is programmed into a Fuseset to thereby cause access to the address in the normal operation state, the redundancy word line RWL programmed with the address value is accessed.

The left side of FIG. 34 shows that defects are individually found in word lines WL10, WL20, and WL30 in first-operation dedicated testing, such as in wafer-level testing, and a first-operation dedicated Fuseset is used to substitute redundancy word lines RWL therefor, thereby having passed the testing. “1st Fuse Blow address” values in FIG. 34 show the fuse programming states.

It is now assumed that when, for example, the chip has been subjected to testing after assembly, and the result showing that the word line WL20 is defect has been obtained. In this case, in the chip after assembly, although fault should have actually occurred with the redundancy word line RWL1, it appears as viewed from the outside of the chip that fault has occurred with the word line WL20. Even when it is assumed that means of externally detecting that RWL1 is defect is available, the word line necessary to be compensated for is the word line WL20. As such, it is assumed that the word line WL20 has been compensated for with an unused redundancy word line RWL4 by using the second-operation dedicated Fuseset. In this case, when the word line WL20 out of the 512 word lines WL is accessed in the normal memory operation state, two redundancy word lines RWL1 and RWL4 are accessed at the same time. In this case, normal circuit operation cannot be guaranteed, and erroneous operation occurs.

“2nd Fuse Blow address” values on the right side in FIG. 34 show the post-programming states of the second-operation dedicated Fusesets. In addition, data to be actually transferred to the memory macro 10 is “transfer Fuse Data”. In the figure, the address value “20” is transferred twice, as circled by dotted lines.

The memory of the eighth embodiment is made to prevent the occurrence of erroneous operation in the case where the same address value is, as described above, programmed into the first- and second-operation dedicated Fusesets.

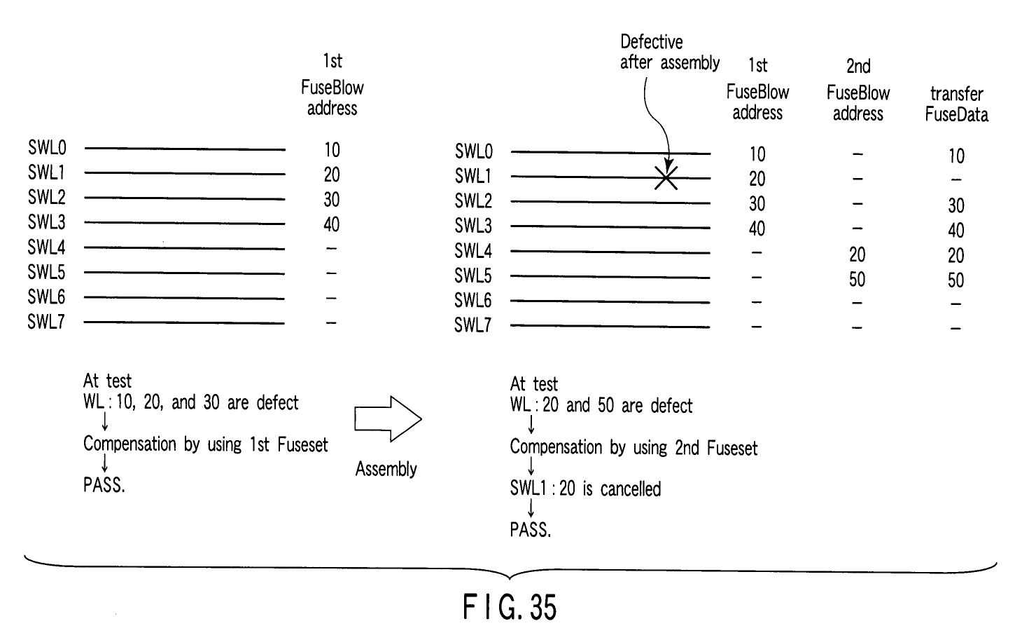

The principles of the memory of the eighth embodiment will now be described herebelow by reference to FIG. 35. Similarly as in the case of FIG. 34, FIG. 35 shows eight redundancy word lines RWL provided for 512 word lines WL, address values to be programmed into Fusesets in the event of using the redundancy word lines RWL, and address values to be actually transferred into the memory macro 10. The left side of the figure shows the state where compensation is performed using a first-operation dedicated Fuseset, and testing performed thereafter has been passed. The right side of the figure shows the state where compensation is performed using a second-operation dedicated Fuseset, and address values to be actually transferred to the memory macro 10.

When faults have been found with word lines WL10 to WL40, in the first testing, these word lines are compensated for by using the word lines RWL0 to RWL3 in the first fuse blowing.

Then, it is assumed that word lines WL20 and WL50 are found in post-assembly testing. Thereafter, the second-operation dedicated Fusesets are programmed, and compensation is performed using unused redundancy word lines.

As in the memories of the sixth embodiment and the modified embodiment thereof, when an address value programmed into the second-operation dedicated Fuseset is transferred as it is to the memory macro 10 through the data transfer control circuit 25, the same address value is transferred twice for the word line WL20. To avoid the problem, in the memory of the present embodiment, ten-bits data to be transferred are monitored for the first-operation dedicated Fuseset. In addition, it is comparatively detected whether or not a same address value exists in the ten-bits data of the second-operation dedicated Fuseset. As a consequence, if a same address value does not exist, then an interrupt determination is performed by indicator bits of a second-operation dedicated Fuseset to find whether or not a same address value exists. Then, the ten-bits data of the first- or second-operation dedicated Fuseset is transferred to the memory macro 10. On the other hand, if a same address value exists, then the ten-bits data of the first-operation dedicated Fuseset wherein the same address value is detected in the second-operation dedicated Fuseset are all set to 0s and transferred to the memory macro 10. Instead of the manner that the ten-bits data of the first-operation dedicated Fuseset are all set to 0s, only the Enable bit may be set to 0. Similarly as in the case of FIG. 33, an interrupt determination by the indicator bits are performed for the data programmed into the second-operation dedicated Fuseset, and data transfer control is performed in accordance with the determination result. Accordingly, the address values to be transferred to the memory macro 10 are for items 10, 30, 40, 20, and 50, as shown under “transfer Fuse Data” of FIG. 35. That is, if a same address value programmed into the second-operation dedicated Fuseset exists, the generation of the same address value is cancelled.

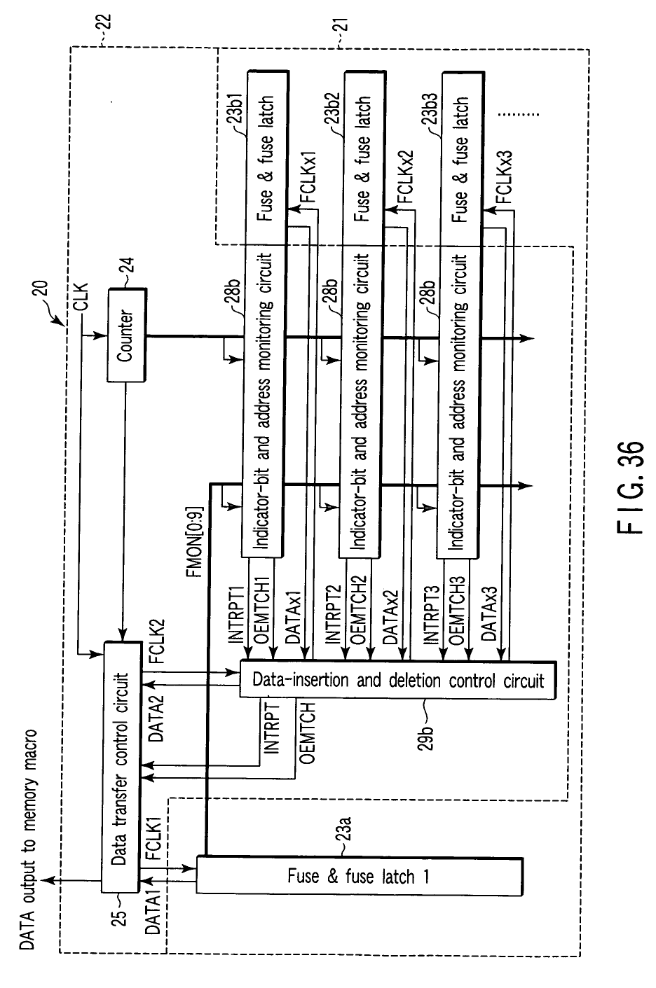

FIG. 36 is a block diagram showing a practical configuration of a fuse box 20 in the memory of the eighth embodiment. The basic configuration of the fuse box 20 in the present embodiment is similar to that shown in FIG. 30, but following respects are different from that shown in FIG. 30.

Instead of the plurality of indicator-bit monitoring circuits 28 of FIG. 30, a plurality of indicator-bit and address monitoring circuits 28b are provided. The indicator-bit and address monitoring circuits 28b are each supplied with data being programmed into the corresponding second fuse and fuse latches 23b1, 23b2, 23b3, etc., and ten-bits data FMON[0:9] being transferred from the first fuse and fuse latch 23a to the data transfer control circuit 25. Before the serial data DATA1 is transferred to the data transfer control circuit 25 from the first fuse and fuse latch 23a, the respective indicator-bit and address monitoring circuit 28b performs a comparison between the ten-bits data FMON[0:9] and the address value pre-programmed into the corresponding second fuse and fuse latches 23b1, 23b2, 23b3, etc., and outputs a match signal OEMTCHi (i=1, 2, 3, etc.) when a matched address value exists. Timing of the comparison of the address value can be controlled by using an output signal of the counter 24.

In addition, Instead of the data insertion control circuit 29 of FIG. 30, a data-insertion and deletion control circuit 29b is provided. Upon reception of the match signal OEMTCHi, the data-insertion and deletion control circuit 29b outputs a match signal OEMTCH to the data transfer control circuit 25. Upon reception of the match signal OEMTCH, the data transfer control circuit 25 cancels data transfer of the address value from the first fuse and fuse latch 23a to the memory macro 10. That is, the generation of the data to be transferred to the memory macro 10 is essentially cancelled.

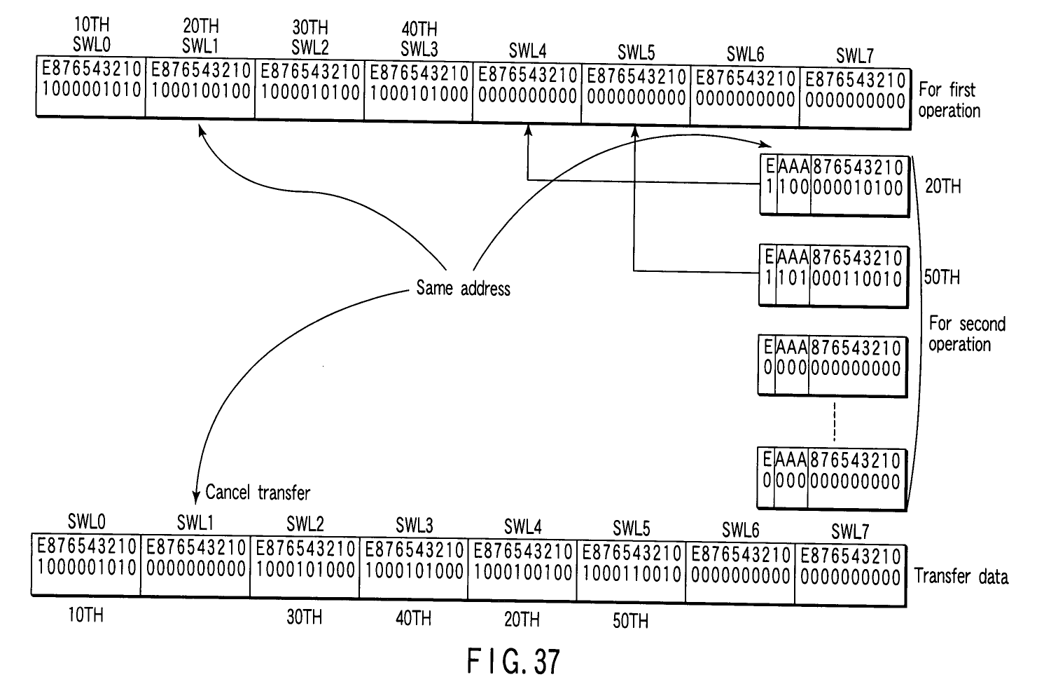

FIG. 37 shows exemplary redundancy information to be written into a first, second fuse and fuse latch provided in the fuse box 20 of FIG. 36 and exemplary data to be transferred to the memory macro 10.

In this case, when performing programming to a first-operation dedicated Fuseset, single-bit data is programmed into the Enable fuse (E) in the first bit position, and an address for specifying an address using the row redundancy is programmed into the remaining nine data bits (address bits). When performing programming to a second-operation dedicated Fuseset, single-bit data is programmed into the Enable fuse (E) in the first bit position, indicator bits are programmed in to three indicator bits (A) subsequent thereto, and an address for specifying an address using the row redundancy is programmed into the remaining nine data bits (address bits).

In the example shown in FIG. 37, address values for items 10 to 40 for substituting for four redundancy word lines RWL0 to RWL3 are programmed into the first-operation dedicated Fuseset. In addition, address values for items 20 and 50 for substituting for two redundancy word lines RWL4 and RWL3 are programmed into the second-operation dedicated Fuseset.

The same address value as address value “20” corresponding to the redundancy word line RWL1 in the first-operation dedicated Fuseset exists in an address value pre-programmed in the second-operation dedicated Fuseset. Accordingly, address value “20” corresponding to the redundancy word line is not transferred, but is cancelled.

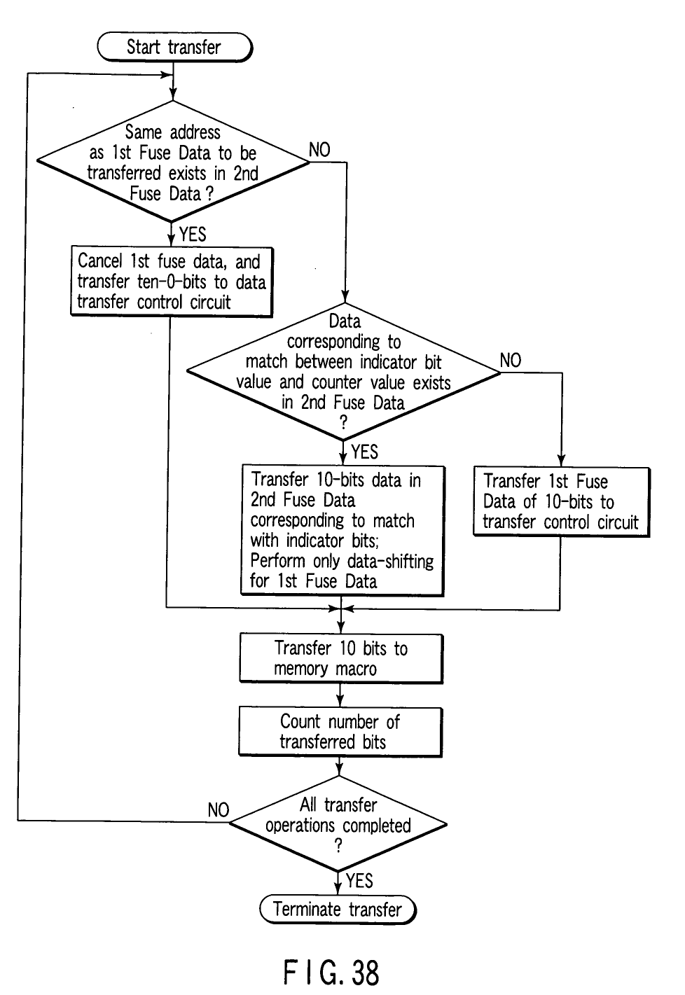

FIG. 38 is a flowchart showing an algorithm used when new redundancy information is created in the data transfer control circuit 25 of the memory according to the eighth embodiment.

In the event of performing data transfer in accordance with the algorithm shown in FIG. 38, when a same address value is programmed in a same row redundancy word line in the first and second operations, the address value is not transferred. More specifically, when the second-operation dedicated Fuseset is programmed, only the operation of canceling the data programmed into the first-operation dedicated Fuseset is performed. This can be applied in such a case where, for example, a proper address cannot be programmed because of occurrence of error in the event of blowing on the first-operation dedicated Fuseset.

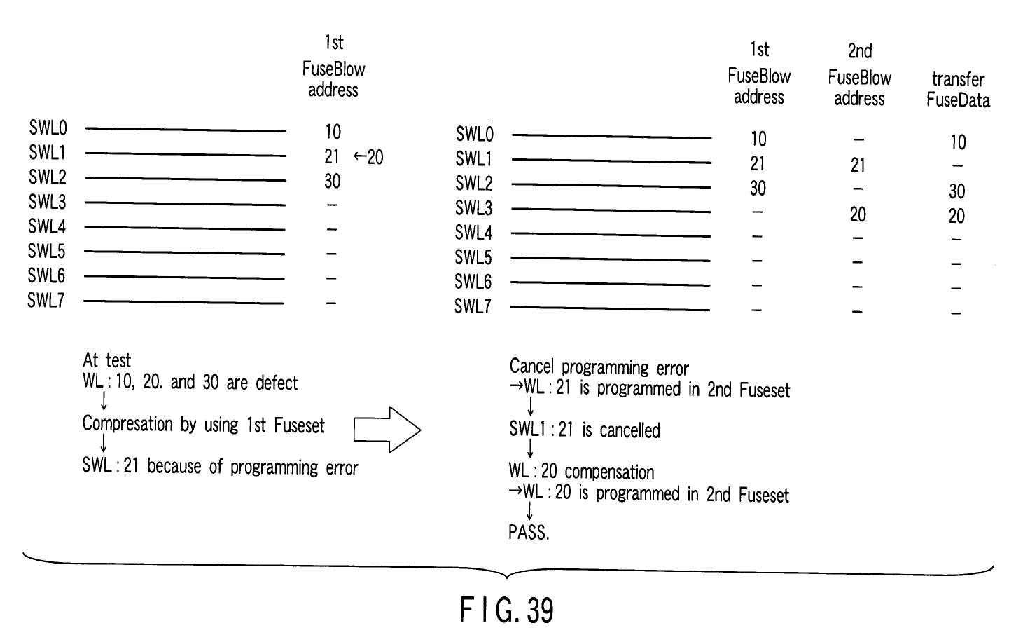

An example in the above case is shown in FIG. 39. The example shows that while address values for items 10 to 30 are intended to be programmed by the first-operation dedicated fuse blowing, item 20 has become item 21 because of programming error. Then, in the second fuse blowing, the redundancy word line RWL1 is designated, the address value for item 20 is programmed, a new row redundancy word line RWL3 is designated, and the address value for item 20 is programmed. Thereby, the address value “20” originally intended can be generated and transferred to the memory macro 10.

In the fuse box 20 having the configuration shown in FIG. 36, the indicator-bit and address monitoring circuit 28b outputs also the interrupt signal. INTRPTi synchronously with the event of outputting the match signal OEMTCHi. When performing control of the type shown in FIG. 39, since the fuse data is desired to be cancelled, the data-insertion and deletion control circuit 29 places precedence on the match signal OEMTCHi and outputs only the match signal OEMTCH, but does not outputs the interrupt signal INTRPT. In this case, the respective indicator-bit and address monitoring circuit 28b may preferably be configured such that when both the match signal OEMTCHi and interrupt signal INTRPTi, only the match signal OEMTCH is output.

Additional advantages and modifications will readily occur to those skilled in the art. Therefore, the invention in its broader aspects is not limited to the specific details and representative embodiments shown and described herein. Accordingly, various modifications may be made without departing from the spirit or scope of the general inventive concept as defined by the appended claims and their equivalents.

What is claimed is:

1. A semiconductor memory device comprising:
a plurality of redundancy information storage circuits each including a plurality of nonvolatile storage elements which store redundancy information used to replace a defective cell existing in a memory cell array by a spare cell in a spare memory cell array; and
a redundancy information creation circuit which receives a plurality of redundancy information stored in the plurality of redundancy information storage circuits, combines the plurality of redundancy information, and thereby creates new redundancy information.

2. The semiconductor memory device according to claim 1, wherein of the plurality of redundancy information stored in the plurality of redundancy information storage circuits, redundancy information stored in at least one redundancy information storage circuit is data-compressed.

3. The semiconductor memory device according to claim 1, wherein the plurality of redundancy information stored in the plurality of redundancy information storage circuits are all data-compressed.

4. The semiconductor memory device according to claim 1, wherein the plurality of redundancy information storage circuits includes a redundancy information storage circuit different in information storage capacity.

5. The semiconductor memory device according to claim 1, wherein the redundancy information creation circuit cancels creation of the new redundancy information in accordance with redundancy information stored in the plurality of redundancy information storage circuits.

6. The semiconductor memory device according to claim 1, wherein the plurality of nonvolatile storage elements includes a plurality of types of nonvolatile storage elements different in programming scheme.

7. The semiconductor memory device according to claim 6, wherein at least one of the plurality of types of the nonvolatile storage elements is programmed by a scheme of irradiating laser light.

8. The semiconductor memory device according to claim 6, wherein at least one of the plurality of types of the nonvolatile storage elements is programmed by an electrical scheme.

9. The semiconductor memory device according to claim 1, wherein the redundancy information creation circuit expands a plurality of redundancy information stored in the plurality of redundancy information storage circuits and acquires logical sums of the plurality of redundancy information expanded, thereby to combine the redundancy information and create the new redundancy information.

10. The semiconductor memory device according to claim 9, wherein an expansion scheme for expanding the plurality of redundancy information includes at least two expansion schemes.

11. The semiconductor memory device according to claim 10, wherein at least one expansion scheme of the at least two expansion schemes is an expansion scheme which expands a compressed bit pattern to a fixed-length bit pattern.

12. The semiconductor memory device according to claim 11, wherein the expansion scheme to expand to the fixed-length bit pattern expands the compressed bit pattern to one of a first bit-length bit pattern or a second bit-length bit pattern.

13. The semiconductor memory device according to claim 10, wherein one expansion scheme of the at least two expansion schemes is configured of address bits and data bits, the contents of the data bits is written in an area in which is designated by the address bits.

14. The semiconductor memory device according to claim 10, wherein one expansion scheme of the at least two expansion schemes outputs redundancy information without being modified.

15. A semiconductor memory device comprising:
a memory cell array having a plurality of memory cells;
a spare memory cell array having a plurality of spare cells used to compensate for a defective cell existing in the memory cell array;
a plurality of redundancy information storage circuits each including a plurality of nonvolatile storage elements which store redundancy information used to replace a defective cell existing in the memory cell array by a spare cell in the spare memory cell array;
a redundancy information creation circuit which receives a plurality of redundancy information stored in the plurality of redundancy information storage circuits, combines the plurality of redundancy information, and thereby creates new redundancy information; and
a selection circuit which receives redundancy information created in the redundancy information creation circuit and selection information for a memory cell existing in the memory cell array, and selects any one of a memory cell existing in the memory cell array and a spare cell existing in the spare memory cell array in accordance with the information received.

16. The semiconductor memory device according to claim 15, wherein of the plurality of redundancy information stored in the plurality of redundancy information storage circuits, redundancy information stored in at least one redundancy information storage circuit is data-compressed.

17. The semiconductor memory device according to claim 15, wherein the plurality of redundancy information stored in the plurality of redundancy information storage circuits are all data-compressed.

18. The semiconductor memory device according to claim 15, wherein the plurality of redundancy information storage circuits includes a redundancy information storage circuit different in information storage capacity.

19. The semiconductor memory device according to claim 15, wherein the redundancy information creation circuit cancels creation of the new redundancy information in accordance with redundancy information stored in the plurality of redundancy information storage circuits.

20. The semiconductor memory device according to claim 15, wherein the plurality of nonvolatile storage elements includes a plurality of types of nonvolatile storage elements different in programming scheme.
